(19) United States
(12) Patent Application Publication
(10) Pub. No.: US 2007/0177355 A1
(43) Pub. Date: Aug. 2, 2007

(54) Heat sink, electronic device, and tuner apparatus

(75) Inventors: Akio Ito, Osaka (JP); Miyoshi Yamauchi, Osaka (JP); Akihiko Doi, Osaka (JP)

Correspondence Address: NIXON & VANDERHYE, PC, 901 NORTH GLEBE ROAD, 11TH FLOOR, ARLINGTON, VA, 22203, US

(73) Assignee: Sharp Kabushiki Kaisha, Osaka-shi (JP)

(21) Appl. No.: 11/634,227

(22) Filed: Dec. 6, 2006

(30) Foreign Application Priority Data
Jan. 30, 2006 (JP) 2006-021288

(51) Int. Cl. H05K 7/20; F28F 7/00

(52) U.S. Cl. 361/709; 165/80.3

(57) ABSTRACT

In one embodiment of a heat sink fitted to an electronic component, a plurality of heat dissipating members having a flat main body portion and a fin portion formed by extending the main body portion are provided, and at least one of the heat dissipating members further has an extended portion formed by extending the fin portion or the main body portion, and an engaging portion formed in a tip of the extended portion.

### CROSS REFERENCE TO RELATED APPLICATIONS

This application claims priority under 35 U.S.C. § 119(a) on Patent Application No. 2006-021288 filed in Japan on Jan. 30, 2006, the entire contents of which are hereby incorporated by reference.

### BACKGROUND OF THE INVENTION

1. Field of the Invention

The present invention relates to a heat sink as a configuration that can engage with a constituent member of an electronic device, and an electronic device and a tuner apparatus that are provided with such a heat sink.

2. Related Art

Electronic devices are configured by mounting electronic components that configure an electric circuit on a mounting substrate. Among electronic components, ICs (integrated circuits) in particular have highly integrated semiconductor elements, and so due to the application of electricity they may reach high temperatures. The operation of an IC that has reached a high temperature may become unstable, and so ICs are equipped with heat sinks.

FIG. 49 is a perspective view of an electronic device with a heat sink fitted to an electronic component.

A heat sink 101 is fitted to the back face of an IC 151 as an electronic component, absorbs heat such that the IC 151 does not become more than a prescribed temperature, and dissipates heat into the surrounding air.

The heat sink 101 is configured from a main body portion 111 that contacts the electronic component and a fin portion 112 provided approximately perpendicular to the main body portion 111. In order to improve the efficiency with which heat is dissipated into the air, a plurality of the fin portions 112 are provided in the main body portion 111. Also, because high thermal conductivity is required for the heat sink 101, it is formed from iron, copper, aluminum or the like. From the viewpoint of mass production, the heat sink 101 is fabricated by a die-casting method or an extrusion method.

The heat sink 101 is fitted to the back face of the IC 151 by being fixed with a thermally conductive adhesive 160 (see FIG. 50). Because the thermally conductive adhesive 160 that affixes the heat sink 101 is exposed to the heat generated by the IC 151, adhesive whose adhesive power is not weakened by heat is used. However, the adhesive power changes over time due to long-term use and the surrounding environment (such as changes in temperature and humidity).

The heat sink 101 is formed from metal, and has a corresponding degree of weight.

Accordingly, when the electronic device 150 is placed standing such that the back face of the IC 151 becomes vertical, adhesion of the heat sink 101 and the IC 151 may gradually be stripped away due to the gravitational force applied to the heat sink 101.

In response, a method is conceivable in which the heat sink 101 is fixed to a case 152 by metal fittings or the like.

FIG. 50 is a side view in which a heat sink, fitted to an electronic component, is viewed from the side in a state fixed to a case by metal fittings or the like. By engaging each of the fin portion 112 and the case 152 to a metal fitting 170 with a screw 171, the heat sink 101 is fixed to the case 152. Thus, even if the adhesive power of the adhesive 160 weakens, the heat sink 101 will not separate from the IC 151. However, because it is necessary to drive the screws 171 into the case 152 and the fin portion 112, such a fixing method takes much time.

In order to address such problems, a pressure spring has been proposed that fixes the beat sink 101 by pressing against it (for example, see JP H9-293980A). When it has been fitted to an electronic component, the heat sink 101 is pressed down by the pressure spring, which is formed along a curve. Both ends of the pressure spring are fixed to a side wall of the electronic component case, in which the electronic component has been loaded.

However, with the technology described in above JP H9-293980A, it is necessary to design the pressure spring to match the shape of the heat sink.

An optimum heat sink is selected in consideration of the heat generating state of the electronic component, the size of the interior space in which the electronic component will be loaded, and the like. Accordingly, it is necessary to design the shape of the pressure spring to match their shape, and such that it presses down the heat sink with reliable force.

### SUMMARY OF THE INVENTION

The present invention was made in view of such circumstances, and it is an object thereof to provide a simply configured heat sink that does not separate from an electronic component, and an electronic device and a tuner apparatus that are provided with such heat sink(s).

A heat sink according to the present invention includes a plurality of heat dissipating members each having a flat main body portion and a fin portion formed by extending the main body portion, in which at least one of the heat dissipating members further has an extended portion formed by extending the fin portion or the main body portion, and an engaging portion formed in a tip of the extended portion.

With this configuration, because the heat sink is engaged to a constituent member of an electronic device equipped with the electronic component by the engaging portion, the heat sink does not separate from the electronic component, and it is possible to reliably dissipate the heat of the electronic component.

Also, the heat sink is configured by combining a plurality of heat dissipating members, and each heat dissipating member has a comparatively simple shape, so it is possible to broaden the range of choices for a manufacturing method. That is, because the heat dissipating members can be manufactured by the most reasonable manufacturing method in consideration of initial cost, production volume, delivery period, the shape of the heat dissipating members, and the like, the cost of the heat sink can be suppressed to a low level.

Also, by appropriately combining the heat dissipating members, the heat sink can be made to have a required heat dissipating capacity. Also, it is possible to exchange part of the heat dissipating members, and so the heat dissipating capacity can easily be altered. That is, even when the electronic component equipped with the heat sink has been changed and there is a fluctuation in the amount of generated heat, it is possible to alter the heat dissipating capacity by merely exchanging part of the heat dissipating members with heat generating members that have a suitable shape.

Also, the heat sink according to the present invention may have a configuration in which the fin portions of the respective heat dissipating members are placed juxtaposed, and the extended portion is formed in a direction that intersects the direction in which the fin portions are placed juxtaposed. With this configuration, it is possible to fix the heat sink by engaging an engaging portion to a constituent member of the electronic device present in a direction that intersects the direction in which the fin portions are placed juxtaposed.

Also, the heat sink according to the present invention may have a configuration in which the fin portions of the respective heat dissipating members are placed juxtaposed, and the extended portion is formed in the direction in which the fin portions are placed juxtaposed.

With this configuration, it is possible to fix the heat sink by engaging an engaging portion to a constituent member of the electronic device present in the direction in which the fin portions are placed juxtaposed.

Also, the heat sink according to the present invention may have a configuration in which the fin portions of the respective heat dissipating members are placed juxtaposed, and the extended portion is formed in a direction that intersects the direction in which the fin portions are placed juxtaposed and in the direction in which the fin portions are placed juxtaposed.

With this configuration, the heat sink is fixed by engaging an engaging portion to a constituent member of the electronic device present in a direction that intersects the direction in which the fin portions are placed juxtaposed, and engaging an engaging portion to a constituent member of the electronic device present in the direction in which the fin portions are placed juxtaposed, and so the heat sink is stably held.

Also, the heat sink according to the present invention may have a configuration in which the extended portion is formed by extending from both ends of a heat dissipating member. With this configuration, the heat sink is engaged to a constituent member of the electronic device at both ends of the heat dissipating member, and the main body portion of the heat sink is uniformly pressed against by the back face of the electronic component, so heat can be adsorbed with good efficiency from the entire back face of the electronic component.

Also, the heat sink according to the present invention may have a configuration in which the engaging portion is formed in a convex shape relative to the tip end face of the extended portion. With this configuration, it is possible to engage the engaging portion to a constituent member of the electronic device in which a concave catch portion has been formed.

Also, the heat sink according to the present invention may have a configuration in which the engaging portion is formed in a concave shape relative to the tip end face of the extended portion. With this configuration, it is possible to engage the engaging portion to a constituent member of the electronic device in which a convex catch portion has been formed.

Also, the heat sink according to the present invention may have a configuration in which the engaging portion is formed in an L shape. With this configuration, it is possible to engage the engaging portion to a constituent member of the electronic device in which a concave catch portion has been formed. Also, it is possible to firmly fix the heat sink to a constituent member by deforming the L-shaped tip.

Also, the heat sink according to the present invention may have a configuration in which the engaging portion is formed in a T shape. With this configuration, it is possible to firmly fix the heat sink to a constituent member because the tip of an engaging portion which has been modified in a T shape can be twisted. Also, because the tip of the engaging portion is twisted, engagement is not released.

Also, the heat sink according to the present invention may have a configuration in which the engaging portion is a flat contact face that makes contact. With this configuration, the heat sink makes contact with a constituent member of the electronic device at a contact face on both ends of a heat dissipating member, and because the heat sink is pushed against from both sides, it is stably held.

Also, the heat sink according to the present invention may have a configuration in which the engaging portion is configured by forming a concave portion in the contact face. With this configuration, the heat sink is contacted by a constituent member of the electronic device at a contact face on both ends of a heat dissipating member and pushed against from both sides, so that it can be engaged to a convex portion formed in the constituent member, and so the heat sink can be stably held with a simple structure.

Also, the heat sink according to the present invention may have a configuration in which the engaging portion is configured by forming a convex portion in the contact face. With this configuration, the heat sink is contacted by a constituent member of the electronic device at a contact face on both ends of a heat dissipating member and pushed against from both sides, so that it can be engaged to a concave portion formed in the constituent member, and so the heat sink can be stably held with a simple structure.

Also, the heat sink according to the present invention may have a configuration in which the engaging portion engages to a case of an electronic device equipped with the electronic component. With this configuration, the heat sink can be simply fixed to the case. Also, because heat can be transmitted to the case, heat dissipation can be further increased.

Also, the heat sink according to the present invention may have a configuration in which the engaging portion engages to a mounting substrate on which the electronic component is mounted. With this configuration, the heat sink can be simply fixed to the case. Also, heat transmitted from the electronic component to the mounting substrate can be dissipated.

Also, the heat sink according to the present invention may have a configuration in which fitting portions that fit with each other are formed on both faces of the main body portion. With this configuration, it is possible to fit the fitting portions together with each other when the heat dissipating members are stacked together at the main body portions, and so it is possible to simply position the heat dissipating members.

Also, the heat sink according to the present invention may have a configuration in which the fin portion has a positioning portion that positions the main body portion by making contact with an adjacent fin portion. With this configuration, the positioning portion makes contact with the fin portion of an adjacent heat dissipating member when the heat dissipating members are stacked together at the main body portions, and so it is possible to simply position the heat dissipating members.

Also, the heat sink according to the present invention may have a configuration in which a joining member is provided that joins a plurality of the heat dissipating members stacked at the main body portions. With this configuration, it is possible to simply press together and join a plurality of heat dissipating members with the joining member.

Also, the heat sink according to the present invention may have a configuration in which the joining member is inserted into a through-hole formed in the main body portion, and the tip is deformed. With this configuration, a plurality of heat dissipating members can be joined with a single operation. Also, because the tip of the joining member is deformed, the heat dissipating members do not separate and come loose.

Also, the heat sink according to the present invention may have a configuration in which the joining member is provided with a male joining component and a fitting component that fits with the male joining component such that it can be attached and removed, and the male joining component is inserted in the through-hole formed in the main body portions and fitted with the joining component.

With this configuration, a plurality of heat dissipating members can be joined with a single operation. Also, after a plurality of the heat dissipating members have been joined, because the male joining component and the fitting component can be detached, one heat dissipating member can be changed with another heat dissipating member. Thus, it is possible to easily modify the heat dissipating capacity.

Also, the heat sink according to the present invention may have a configuration in which the heat dissipating members are stacked such that the end faces of the main body portions are even, the furthest outside heat dissipating member has a protruding portion that protrudes from the end face, and the protruding portion is deformed such that it presses against the main body portions.

With this configuration, because the heat dissipating members can be joined by deforming the protruding portion, and so the heat dissipating members can easily be joined. Also, because a joining member for joining the heat dissipating members is not necessary, it is possible to reduce the number of components.

Also, the heat sink according to the present invention may have a configuration in which a concave-shaped fitting concave portion into which the protruding portion fits is each formed in the end faces of other heat dissipating members loaded on the furthest outside heat dissipating member. With this configuration, when the heat dissipating members are joined with the protruding portion deformed, the protruding portion can be fitted into the fitting concave portion, and so it is possible to match the positions of the heat dissipating members based on the protruding portion.

Also, the heat sink according to the present invention may have a configuration in which the fitting concave portion is a notch. With this configuration, because all or a part of the protruding portion is buried in the notch, it is possible for all or a part of the protruding portion to not protrude from the end face of the heat sink.

Also, the heat sink according to the present invention may have a configuration in which the fitting concave portion is configured by a projection or projections provided in the end face of the main body portion. With this configuration, the protruding portion can easily be fit together with the fitting concave portion. That is, the protruding portion is bent at the base of the end face of the main body portion, and so it can be deformed to follow the end face of the heat dissipating members.

Also, the heat sink according to the present invention may have a configuration in which the heat dissipating members are welded to each other. With this configuration, it is possible to firmly join the heat dissipating members.

Also, the heat sink according to the present invention may have a configuration in which the heat dissipating members are soldered to each other. With this configuration, the heat dissipating members can be put in contact with a simple tool.

Also, the heat sink according to the present invention may have a configuration in which the heat dissipating members are adhered to each other with thermally conductive adhesive. With this configuration, because it is possible to adhere the heat dissipating members at the entire bottom face of the main body portions, and the gap between one main body portion and another main body portion can be filled, so it is possible to improve the heat dissipating efficiency.

Also, the heat sink according to the present invention may have a configuration in which the heat dissipating members are adhered to each other with two-sided tape. With this configuration, the heat dissipating members can be adhered with a simple operation.

Also, the heat sink according to the present invention may have a configuration in which at least one of the heat dissipating members is formed from aluminum. With this configuration, it is possible to lighten the weight of the heat sink. Thus, the gravitational force applied to the heat sink is reduced, and the force that acts between the electronic component and the heat sink can be lessened.

Also, the heat sink according to the present invention may have a configuration in which at least one of the heat dissipating members is formed from copper. With this configuration, because the thermal conductivity ratio of copper is high, it is possible to improve the heat dissipation of the heat sink.

Also, the heat sink according to the present invention may have a configuration in which the heat dissipating member having the engaging portion is formed from tin plate. With this configuration, because tin plate has good solderability, it is possible to easily solder the constituent members that configure the electronic device and the engaging portion. Thus, the heat sink is firmly fixed to the constituent members.

Also, the heat sink according to the present invention may have a configuration in which convexo-concaves are formed on the surface of the fin portion. With this configuration, because the surface area of the fin portion increases, it is possible to increase the heat dissipating capacity.

Also, the heat sink according to the present invention may have a configuration in which through-holes are provided in the fin portion. With this configuration, because the surface area of the fin portion increases, it is possible to increase the heat dissipating capacity. Also, it is possible to prevent the stagnation of air around the heat sink. Thus, heat is efficiently dissipated.

Also, the heat sink according to the present invention may have a configuration in which through-holes are provided in the main body portion. With this configuration, because the surface area of the main body portion increases, it is possible to increase the heat dissipating capacity. Also, it is possible to allow direct contact between the electronic component on which the heat sink is mounted and the surrounding air. Thus, the heat dissipating efficiency further improves.

Also, the heat sink according to the present invention may have a configuration in which the height of the fin portion is allowed to vary according to the heat distribution in the electronic component.

With this configuration, it is possible to avoid making the main body portion larger than necessary, so that the heat sink can be made smaller. That is, the fin portion corresponding to the portion in which a semiconductor chip is mounted is made taller, and the fin portion is made shorter in other portions, varying the height of the fin portion. Thus, unnecessary fin portions can be removed, and so it is possible to make a smaller and lighter heat sink.

Also, the heat sink according to the present invention may have a configuration in which the fin portion is provided with a heat dissipating extended portion. With this configuration, because the fin portion expands, it is possible to increase the heat dissipating capacity. Because the fin portion is expanded without increasing the dimensions of the main body portion, its mounting area can be made comparatively small relative to the increase in heat dissipating capacity.

Also, the heat sink according to the present invention may have a configuration in which the cross-sectional shape of the heat dissipating members is bathtub-like in a direction that intersects the direction in which the fin portions are placed juxtaposed. With this configuration, the heat dissipating members can be easily formed, and have a shape easily stacked at the main body portions, so the cost of the heat sink is reduced.

An electronic device according to the present invention includes an electronic component that generates heat due to the application of electricity, any of the above heat sinks fitted to the electronic component, and a constituent member in which a catch portion is formed, in which the engaging portion of the heat sink is engaged to the catch portion.

With this configuration, the heat sink is engaged to the catch portion of the constituent member of the electronic component with the engaging portion, and held by the constituent members, so the heat of the electronic component can be stably dissipated without the heat sink separating from the electronic component.

Also, because the gravitational force applied to the heat sink is dispersed to the constituent members by the engagement of the engaging portion and the catch portion, it is possible to reduce the force applied to the heat sink and the mounting face of the electronic component, so stripping away of the heat sink from the electronic component is eliminated. Thus, the operation of the electronic device is stable, and reliability increases.

Also, the electronic device according to the present invention may have a configuration in which the heat sink is a heat sink according to the present invention, and the catch portion has a concave shape that engages with the engaging portion. With this configuration, the heat sink is simply fixed to the electronic device, so the installation cost of the heat sink can be reduced.

Also the electronic device according to the present invention may have a configuration in which the heat sink is a heat sink according to the present invention, and the catch portion has a convex shape with which the engaging portion engages. With this configuration, the heat sink is simply fixed to the electronic device, so the installation cost of the heat sink can be reduced.

Also, the electronic device according to the present invention may have a configuration in which the heat sink is a heat sink according to the present invention, and the catch portion is provided with a catch main portion that engages with the engaging portion and a fitting portion into which the tip of the engaging portion, having been deformed, is fit.

With this configuration, an L-shaped engaging portion engages to a concave-shaped catch portion, and the deformed end of the engaging portion can be fit in the fitting portion, so the heat sink can be firmly fixed to a constituent member.

Also, the electronic device according to the present invention may have a configuration in which the heat sink is a heat sink according to the present invention, the catch portion has a concave shape with which the engaging portion engages, and the tip of the engaging portion is twisted. With this configuration, the tip head portion of the engaging portion can be twisted in a state with the engaging portion engaged to the catch portion, so the heat sink can be firmly fixed to a constituent member.

Also, the electronic device according to the present invention may have configuration in which the heat sink is a heat sink according to the present invention, and the catch portion is a contact portion in which the contact face is pushed against. With this configuration, the heat dissipating members of the heat sink are fixed by being pushed against on both sides, so it is possible to fix the heat sink to a constituent member with a simple configuration.

Also, the electronic device according to the present invention may have a configuration in which the constituent member is a case. With this configuration, because the heat sink is held by the case, the heat sink does not strip away from the electronic component, so the action of dissipating the heat of the electronic component is insured for a long time, so the reliability of the electronic device improves. Also, the heat of the electronic component is dissipated via the heat sink and the case, so the heat dissipating efficiency improves and the operation of the electronic device is stable.

Also, the electronic device according to the present invention may have a configuration in which the constituent member is a mounting substrate on which the electronic component is mounted. With this configuration, the heat sink is held by the mounting substrate, so the heat sink does not strip away from the electronic component, so the action of dissipating the heat of the electronic component is insured for a long time, so the reliability of the electronic device improves. Also, the heat of the electronic component is transmitted via the mounting substrate to the heat sink, so the heat dissipating efficiency improves and the operation of the electronic device is stable.

Also, the electronic device according to the present invention may have a configuration in which the fin portion has a height at which it is housed inside the case. With this configuration, the heat sink is housed inside the case, and the electronic device is flat as a whole when viewed from outside, so it can be made easily mounted. Also, the entrance of foreign bodies from outside can be prevented, so malfunction of the electronic device is eliminated.

Also, a tuner apparatus according to the present invention includes an input portion that inputs a high frequency signal, a high frequency processing portion that processes the high frequency signal, a video processing portion that converts the signal produced by the high frequency processing portion to a video signal, any of the above heat sinks mounted on an electronic component that configures the video processing portion, and a constituent member in which a catch portion is formed, in which the engaging portion included in the heat sink is engaged to the catch portion.

With this sort of configuration, it is possible with one apparatus to perform high frequency signal processing to video signal processing of a high frequency signal and output it as a video signal. Also, the heat sink is mounted on an electronic component that handles a video processing portion, and the heat sink is engaged to a constituent member, so the electronic component is prevented from reaching unusually high temperatures. Thus, the high frequency signal can be stably processed into a video signal.

Also, the mounted heat sink has a configuration in which the heat dissipating members can easily be changed, so in the tuner apparatus, an appropriate heat sink can be mounted even if the electronic component is changed due to design modifications or the like.

With the heat sink according to the present invention, the heat sink can be held by being engaged to a constituent member of the electronic device with the engaging portion formed in the tip of the extended portion.

Also, with the heat sink according to the present invention, the extended portion is formed extended in both directions, so the heat sink is engaged to a constituent member on both ends of the heat dissipating members, so that the main body portion of the heat sink is uniformly pressed against by the back face of the electronic component, so heat can be efficiently absorbed from the entire back face of the electronic component.

Also, with the heat sink according to the present invention, the engaging portion is formed in a convex, concave, L, or T shape, or a shape having a contact face, so the heat sink can be simply and reliably engaged to a constituent member.

Also, with the heat sink according to the present invention, the constituent member is a case for the electronic device, so heat can be transmitted to the case, so the heat dissipation can be further improved.

Also, with the heat sink according to the present invention, the constituent member is a mounting substrate on which the electronic component has been mounted, so heat transmitted from the electronic component to the mounting substrate can be dissipated.

Also, with the heat sink according to the present invention, in the heat dissipating members, fitting portions that fit with each other are formed in both faces of the main body portion, so the fitting portions can be fit together when the heat dissipating members are stacked at the main body portions, so it is possible to easily position the heat dissipating members.

Also, with the heat sink according to the present invention, the fin portion has a positioning portion that makes contact with an adjacent fin portion, so it is possible to easily position the heat dissipating members.

Also, with the heat sink according to the present invention, a joining member that joins the heat dissipating members when they are stacked at the main body portions is provided, and so a plurality of heat dissipating members can easily be joined.

Also, with the heat sink according to the present invention, the heat dissipating members are stacked so that the end faces of the main body portions are even, and a protruding portion formed protruding from the end face of the heat dissipating member that is furthest outside is deformed such that it presses against the main body portion, so the heat dissipating members can easily be joined.

Also, with the heat sink according to the present invention, at least one heat dissipating member is formed from aluminum, so the weight of the heat sink can be lightened. Thus, the gravitational force applied to the heat sink is reduced, so the force that acts between the electronic component and the heat sink can be lessened.

Also, with the heat sink according to the present invention, in the heat dissipating members, convexo-concaves are formed on the surface of the fin portion, so the surface area of the fin portion is increased, so the heat dissipating capacity can be increased.

Also, with the heat sink according to the present invention, in the heat dissipating members, through-holes are provided in the fin portion or the main body portion, so the surface area of the fin portion or the main body portion increases, so the heat dissipating capacity can be increased.

Also, with the heat sink according to the present invention, in the heat dissipating members, the height of the fin portion is varied according to the heat distribution in the electronic component, so it is possible to avoid making the main body portion larger than necessary, and the heat sink can be made smaller.

Also, with the heat sink according to the present invention, in the heat dissipating members, a heat dissipating extended portion formed by extending the fin portion is provided, so the fin portion is enlarged, and so it is possible to increase the heat dissipating capacity.

Also, with the heat sink according to the present invention, the cross-section of the heat dissipating members is bathtub-shaped, so they are easily formed and have a shape that is easily stacked at the main body portions, so the cost of the heat sink can be decreased.

With the electronic device according to the present invention, a heat sink according to the present invention is mounted, and the engaging portion is engaged to the catch portion formed in a constituent member of the electronic device, so the heat sink does not separate from the electronic component, and the heat of the electronic component can be stably dissipated, so the operation of the electronic device is stable.

Also, with the electronic device according to the present invention, a heat sink according to the present invention is mounted, engaging portions are formed in a convex, concave, L, or T shape, or a shape having a contact face, catch portions corresponding to these engaging portions are formed in a constituent member, and the engaging portions and the catch portions are engaged, so the heat sink can easily be fixed to the electronic device.

Also, with the electronic device according to the present invention, the constituent member is a case of the electronic device, so the heat sink is held by being engaged to the case, and heat is transmitted to the case, so the heat dissipating efficiency is improved and the operation of the electronic device is stable.

Also, with the electronic device according to the present invention, the constituent member is a mounting substrate on which the electronic component has been mounted, so the heat of the electronic component is transmitted to the heat sink via the mounting substrate, so the heat dissipating efficiency is improved and the operation of the electronic device is stable.

Also, with the electronic device according to the present invention, the fin portions are housed inside the case, so the electronic device is flat as a whole when viewed from outside, so it can be made easily mounted.

Also, with the tuner apparatus according to the present invention, in a tuner apparatus that processes a high frequency signal, an input portion that inputs the high frequency signal, a high frequency processing portion that processes the high frequency signal, and a video processing portion that converts the signal produced by the high frequency processing portion to a video signal are provided. A heat sink according to the present invention is mounted on an electronic component that handles the video processing portion, and a constituent member of the tuner apparatus is engaged with an engaging portion, so it is possible with one apparatus to perform high frequency signal processing to video signal processing of a high frequency signal and output it as a video signal. Also, the electronic component is prevented from reaching unusually high temperatures, so the high frequency signal can be stably processed into a video signal.

### BRIEF DESCRIPTION OF THE DRAWINGS

FIG. 1 is a top view in which an electronic device equipped with a heat sink according to Embodiment 1 of the present invention is viewed from above.

FIG. 2 is a cross-sectional view of the electronic device viewed from arrow II in FIG. 1.

FIG. 3 is a perspective view in which the heat sink according to Embodiment 1 of the present invention is viewed obliquely from above.

FIG. 4 is a top view in which the heat sink in FIG. 3 is viewed from above.

FIG. 5 is a side view of the heat sink in FIG. 3.

FIG. 6 is a top view of an electronic device in which the heat sink according to Embodiment 1 of the present invention has been engaged to a case by an engaging portion.

FIG. 7 is an enlarged cross-sectional view in which the engaging portion of the heat sink in FIG. 6 is viewed from arrow B in FIG. 6.

FIG. 8 is a side view of the case of the electronic device equipped with the heat sink in FIG. 6, viewed from arrow C in FIG. 6.

FIG. 9 is a side view of the case of the electronic device equipped with the heat sink according to Embodiment 1 of the present invention, viewed from arrow C in FIG. 6.

FIGS. 10A to 10C are enlarged views of an L portion in FIG. 9 in the electronic device equipped with the heat sink in FIG. 9. FIG. 10A is a state diagram showing the engaging portion in an unengaged state, FIG. 10B is a state diagram showing the engaging portion in an engaged state, and FIG. 10C is a state diagram showing the engaging portion in a restrained state.

FIG. 11 is an enlarged cross-sectional view in which an engaging portion of a heat sink according to a first modified example of Embodiment 1 of the present invention is viewed from arrow B in FIG. 6.

FIG. 12 is a cross-sectional view in which an engaging portion of a heat sink according to a second modified example of Embodiment 1 of the present invention is viewed from arrow B in FIG. 6, in which the engaging portion is in an undeformed state.

FIG. 13 is a cross-sectional view showing the engaging portion in FIG. 12 in a deformed state.

FIGS. 14A and 14B are side views in which the case of the electronic device equipped with the heat sink in FIG. 12 is viewed from arrow C in FIG. 6. FIG. 14A is a side view showing a catch portion in an unengaged state, and FIG. 14B is a side view showing the catch portion in an engaged state.

FIGS. 15A and 15B are illustrative diagrams that illustrate an engaging portion of a heat sink according to a third modified example of Embodiment 1 of the present invention. FIG. 15A is a cross-sectional view in which the engaging portion is viewed before being deformed from arrow B in FIG. 6, and FIG. 15B is a side view in which the engaging portion is viewed after being deformed from arrow C in FIG. 6.

FIG. 16 is a top view of an electronic device in which a heat sink according to a fourth modified example of Embodiment 1 of the present invention has been engaged to a case by an engaging portion.

FIGS. 17A and 17B are cross-sectional views in which the engaging portion of the heat sink in FIG. 16 is viewed from arrow D in FIG. 16. FIG. 17A is a cross-sectional view of a mode in which a concave portion is provided in a contact face as the engaging portion, and FIG. 17B is a cross-sectional view of a mode in which the contact face as the engaging portion is fixed to the case with a screw.

FIG. 18 is a top view in which an electronic device equipped with a heat sink according to Embodiment 2 of the present invention is viewed from above.

FIG. 19 is a perspective view of the heat sink in FIG. 18 viewed obliquely from above.

FIG. 20 is a top view of the heat sink in FIG. 18 viewed from above.

FIG. 21 is a side view of the heat sink in FIG. 18.

FIG. 22 is a top view in which an electronic device equipped with a heat sink according to Embodiment 3 of the present invention is viewed from above.

FIG. 23 is a perspective view of the heat sink in FIG. 22 viewed obliquely from above.

FIG. 24 is a cross-sectional view of an engaging portion of the heat sink in FIG. 22 viewed from arrow XXIV in FIG. 22.

FIG. 25 is a separated view in which a heat sink according to Embodiment 4 of the present invention is separated into each heat dissipating member.

FIG. 26 is a perspective view in which the heat sink in FIG. 26 is viewed obliquely from above.

FIG. 27 is a cross-sectional view of the heat sink viewed from arrow XXVII in FIG. 26.

FIG. 28 is a top view in which a heat sink according to Embodiment 5 of the present invention is viewed from above.

FIG. 29 is a cross-sectional view in which a heat sink according to Embodiment 6 of the present invention is viewed from arrow E in FIG. 26.

FIG. 30 is a cross-sectional view in which a heat sink according to a modified example of Embodiment 6 of the present invention is viewed from arrow E in FIG. 26.

FIG. 31 is a perspective view of a heat sink according to Embodiment 7 of the present invention viewed obliquely from above.

FIG. 32 is a perspective view of a heat dissipating member furthest outside in the heat sink in FIG. 31, viewed obliquely from above.

FIG. 33 is a cross-sectional view of the heat sink viewed from arrow XIII in FIG. 31.

FIG. 34 is a top view of a heat sink with a structure in which it is positioned by a protruding portion, as a first modified example of Embodiment 7 of the present invention.

FIG. 35 is an exploded view in which the heat sink in FIG. 34 is exploded.

FIG. 36 is a top view of a heat sink with another structure in which it is positioned by a protruding portion, as a second modified example of Embodiment 7 of the present invention.

FIG. 37 is an exploded view in which the heat sink in FIG. 36 is exploded.

FIG. 38 is a cross-sectional view in which a heat sink according to Embodiment 8 of the present invention is viewed from arrow E in FIG. 26.

FIG. 39 is a cross-sectional view in which a heat sink according to a modified example of Embodiment 8 of the present invention is viewed from arrow E in FIG. 26.

FIGS. 40A and 40B show a heat sink according to Embodiment 9 of the present invention. FIG. 40A is a top view in which the heat sink is viewed from above, and FIG. 40B is an enlarged view of a portion M.

FIGS. 41A and 41B show a heat sink according to a first modified example of Embodiment 9 of the present invention. FIG. 41A is a top view in which the heat sink is viewed from above, and FIG. 41B is a side view in which the heat sink is viewed from arrow XXXXIB.

FIGS. 42A and 42B show a heat sink according to a second modified example of Embodiment 9 of the present invention. FIG. 42A is a top view in which the heat sink is viewed from above, and FIG. 42B is an enlarged view of a portion N.

FIG. 43 is a top view in which a heat sink according to Embodiment 10 of the present invention is viewed from above.

FIG. 44 is a side view in which the heat sink in FIG. 43 is viewed from arrow XXXXIV in FIG. 43.

FIG. 45 is a side view in which the heat sink in FIG. 43 is viewed from arrow XXXXV in FIG. 43.

FIG. 46 is a top view in which a heat sink according to a modified example of Embodiment 10 of the present invention is viewed from above.

FIG. 47 is a side view in which the heat sink in FIG. 46 is viewed from arrow XXXXVII in FIG. 46.

FIG. 48 is a top view in which a tuner apparatus according to Embodiment 12 of the present invention is viewed from above.

FIG. 49 is a perspective view of an electronic device in which a conventional heat sink has been fitted to an electronic component.

FIG. 50 is a side view in which a conventional heat sink, fitted to an electronic component, is viewed from the side in a state fixed to a case by metal fittings or the like.

### DESCRIPTION OF THE PREFERRED EMBODIMENTS

Hereinafter, embodiments of the present invention will be described with reference to the accompanying drawings.

### Embodiment 1

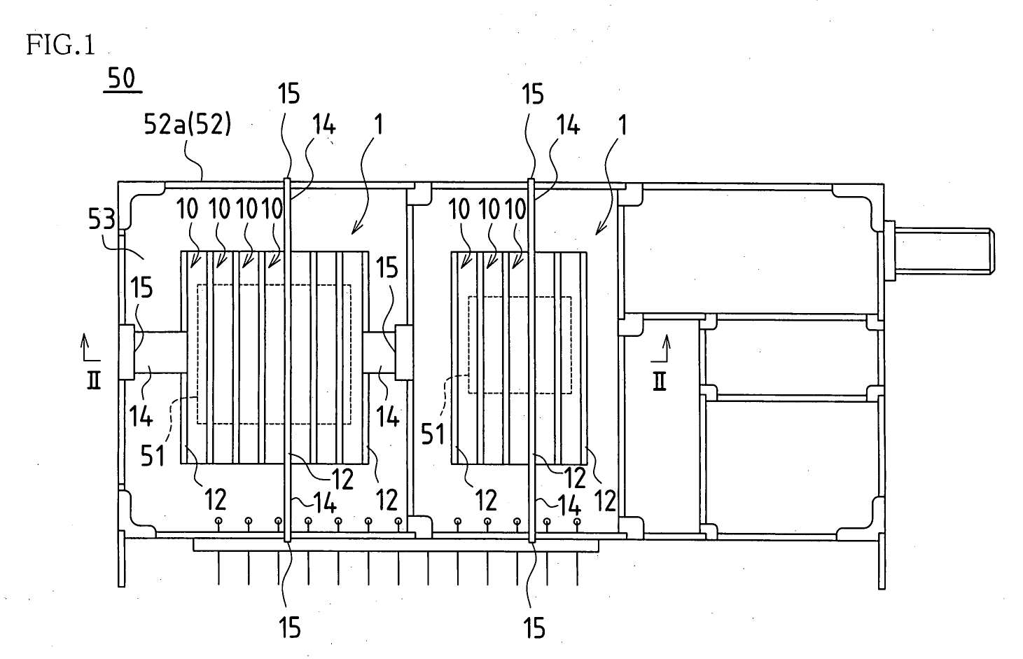

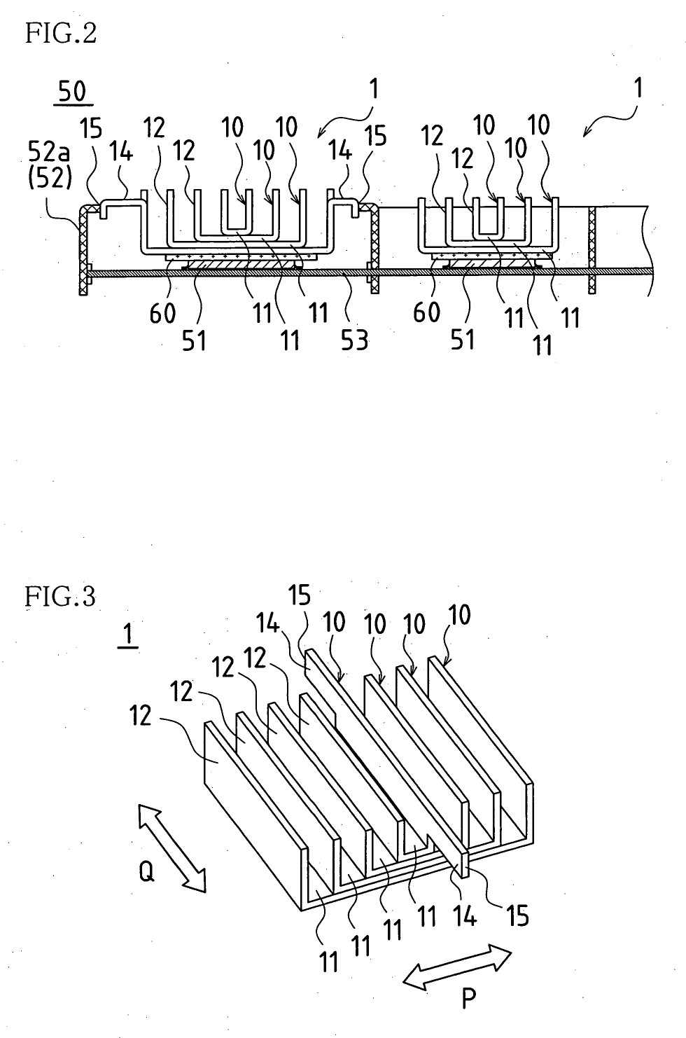

FIG. 1 is a top view in which an electronic device equipped with a heat sink 1 according to a first embodiment of the present invention is viewed from above. FIG. 2 is a cross-sectional view of the electronic device viewed from arrow II in FIG. 1.

The heat sink 1 according to an embodiment of the present invention is configured from a plurality of heat dissipating members 10. The heat dissipating member 10 is provided with a main body portion 11 and a fin portion 12, and an extended portion 14 is formed in the fin portion 12. Further, an engaging portion 15 is formed in the tip of the extended portion 14.

The size of each heat dissipating member 10 varies, but in order to simplify the below description, they are treated together as the heat dissipating members 10 when distinguishing them is not necessary, and they are distinguished by adding a lower case letter (“a”, for example) to the reference numeral “10” only when necessary.

The heat sink 1 is fitted to an electronic component 51 mounted on a mounting substrate 53 of an electronic device 50. The engaging portion 15 is engaged to a constituent member (a case 52 or the mounting substrate 53, see FIG. 1) that constitutes the electronic device 50.

Specifically, the heat sink 1 is fitted to the back side of a surface-mount-type IC (integrated circuit) as the electronic component 51 with a thermally conductive adhesive 60. The heat of the IC is released into the air via the heat sink 1. Also, the engaging portion 15 is engaged to a side wall 52a of the case 52.

Thus, because the heat sink 1 is held by the constituent members of the electronic device 50, it does not separate from the electronic component 51. For example, when the electronic device 50 is provided such that the back face of the electronic component 51 points in the vertical direction, the force of gravity applied to the heat sink 1 acts in the direction that it attempts to strip away adhesion with the electronic component 51 and separation occurs between the heat sink 1 and the electronic component 51, but such separation is eliminated because the force of the heat sink 1 is dispersed in the case 52 by the engaging portion 15.

Following is a description of the specific structure of the heat sink 1 according to the present invention.

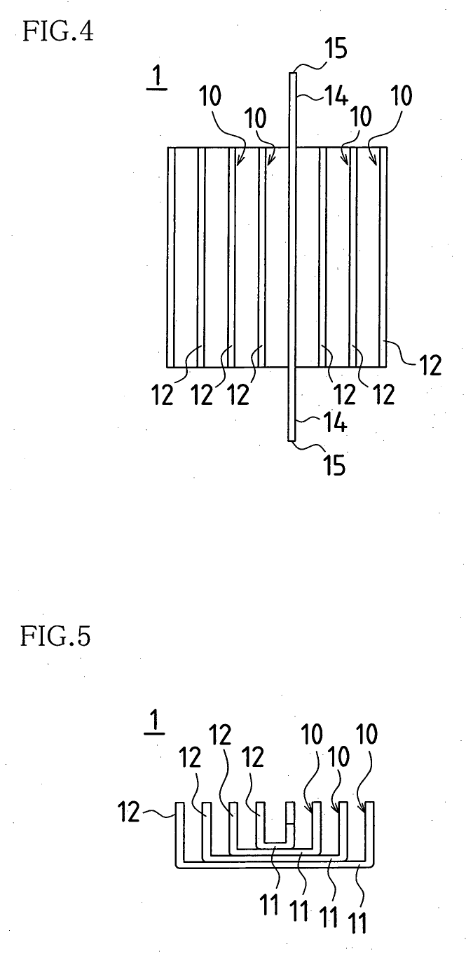

FIG. 3 is a perspective view in which the heat sink 1 according to Embodiment 1 of the present invention is viewed obliquely from above. FIG. 4 is a top view in which the heat sink 1 is viewed from above. FIG. 5 is a side view of the heat sink 1.

The heat sink 1 according to the present embodiment is assembled by stacking a plurality of the heat dissipating members 10 at the main body portions 11. Specifically, the heat dissipating members 10 are stacked in a nested manner in an order that the area of the main body portions 11 becomes smaller.

The heat sink 1 is not limited to a configuration stacked at the main body portions 11. For example, a heat sink may be configured by, using one heat dissipating member 10 as the main body, disposing other heat dissipating members 10 lined up on top of the main body portion 11 of the heat dissipating member 10 used as the main body.

Due to configuring the heat sink 1 by combining a plurality of the heat dissipating members 10, it is possible to appropriately combine the heat dissipating members 10 so the heat sink 1 has a required heat dissipating capacity. Also, because it is possible to exchange some of the heat dissipating members 10, the heat dissipating capacity can easily be altered. Thus, even when the amount of heat generated has been altered by altering the electronic component 51 to which the heat sink 1 is fitted, the heat dissipating capacity can be altered by merely exchanging some of the heat dissipating members 10 with suitably shaped heat dissipating members 10.

Also, because the heat dissipating member 10 has a comparatively simple shape, it is possible to broaden the range of choices for a manufacturing method. That is, because the heat dissipating members 10 can be manufactured by the most reasonable manufacturing method in consideration of initial cost, production volume, delivery period, shape of the heat dissipating members, and the like, the cost of the heat sink 1 can be suppressed to a low level. For example, in the case of products produced in small quantities, the heat dissipating members 10 can be manufactured by a press method, which has low initial cost, and in the case of mass production, the heat dissipating members 10 can be formed by an extrusion method, so that a suitable production method can be selected.

Also, the heat dissipating member 10 is configured with the fin portion 12 provided in the flat main body portion 11. The fin portion 12 has a function of dissipating heat that the main body portion 11 has absorbed from the electronic component 51 into the air. The fin portion 12 is each provided vertically at both ends (or one end) of the main body portion 11 with an open center area in the main body portion 11 such that the heat dissipating members 10 can be stacked at the main body portions 11. Specifically, viewed from direction Q perpendicular to the direction in which the fin portion 12 is provided vertically, the cross-sectional shape of the heat dissipating member 10 is like a bathtub.

By adopting a bathtub-like shape, because the shapes of the heat dissipating members 10 are simple, they can be easily manufactured with a press machine, extrusion method, or the like. Also, the heat dissipating members 10 become easily stacked at the main body portions 11.

Also, the heat dissipating members 10 are placed juxtaposed such that the fin portions 12 are approximately parallel (below, the direction in which the fin portions 12 are placed juxtaposed is referred to as juxtaposed placement direction P). By disposing the heat dissipating members 10 such that the fin portions 12 are disposed parallel to each other, it is possible to stack a plurality of the heat dissipating members 10 at the main body portions 11. Thus, the fin portions 12 can be closely juxtaposed, and it is possible to improve the heat dissipating efficiency of the heat sink 1 relative to the mounting area.

The front face and the back face of the main body portion 11 are smoothly formed such that they closely make contact with each other. Thus, the heat dissipating members 10 can be stacked at the main body portions 11 such that a gap does not occur, and so it is possible to improve the heat transfer ratio. Also, the main body portion 11 is formed in a shape close to that of the electronic component 51 that is fitted (an approximately rectangular shape). By giving the heat sink 1 a shape close to that of the electronic component 51 to which it is fitted, it is possible to effectively adsorb heat, and excess mounting area can be eliminated.

The extended portion 14 is formed by extending the fin portion 12 in one of the heat dissipating members 10 selected as desired. The extended portion 14 is extended in a direction that intersects the juxtaposed placement direction P of the fin portion 12 (an approximately perpendicular direction). Specifically, in the heat dissipating member 10 that has been stacked uppermost, the extended portion 14 is formed such that it extends from both ends of the fin portion 12 and reaches the side wall 52a of the case 52 (see FIG. 1). The extended portion 14 may also be formed extending from the main body portion 11. Also, the extended portion 14 may be formed in any of the heat dissipating members 10; it is not limited to the heat dissipating member 10 that has been stacked uppermost.

It is preferable to form the extended portion 14 in a direction that crosses the approximate center of the back face of the electronic component 51, such that it extends towards both outer sides of the electronic component 51. By configuring the extended portion 14 in this way, it is possible to uniformly press the heat sink 1 against the back face of the electronic component 51, and so heat can be effectively adsorbed from the electronic component 51.

The engaging portion 15 is formed in the tips of the extended portion 14, with a shape that engages the constituent members (the case 52 and the mounting substrate 53, see FIG. 1). Due to the engaging portion 15 engaging the constituent members, the heat sink 1 is held by and fixed to the electronic device 50. Thus, separation of the heat sink 1 from the electronic component 51 is eliminated.

The heat dissipating members 10 are formed with metal having high thermal conductivity. For example, copper, iron, aluminum, an alloy having these metals as its main components, or the like is used. The material used for the heat dissipating members 10 is not limited to metal; ceramics or the like may also be used.

When aluminum is used for the heat dissipating members 10, the weight of the heat sink 1 can be lightened. Thus, because less gravitational force is applied to the heat sink 1, the force applied to the electronic component 51 can be reduced. Specifically, because some of the weight of the heat sink 1 is applied to a surface-mount-type electronic component 51, the stress and the like applied to the electronic component 51 can be reduced. Thus, the reliability of the electronic device 50 equipped with the electronic component 51 can be improved.

Also, when copper is used as the heat dissipating members 10, it is possible to improve the heat dissipation of the heat sink 1.

The heat dissipating member 10 that has the engaging portion 15 may also be formed from tin plate. That is, because tin plate has good solderability, the constituent members that constitute the electronic device 50 (for example, the case 52 made of tin plate and the mounting substrate 53 in which a copper pattern has been formed) and the engaging portion 15 can easily be joined by soldering. Thus, the heat sink 1 is firmly fixed to the constituent members.

Following is a description of several examples of the engaging portion 15 formed in the extended portion 14 of the fin portion 12.

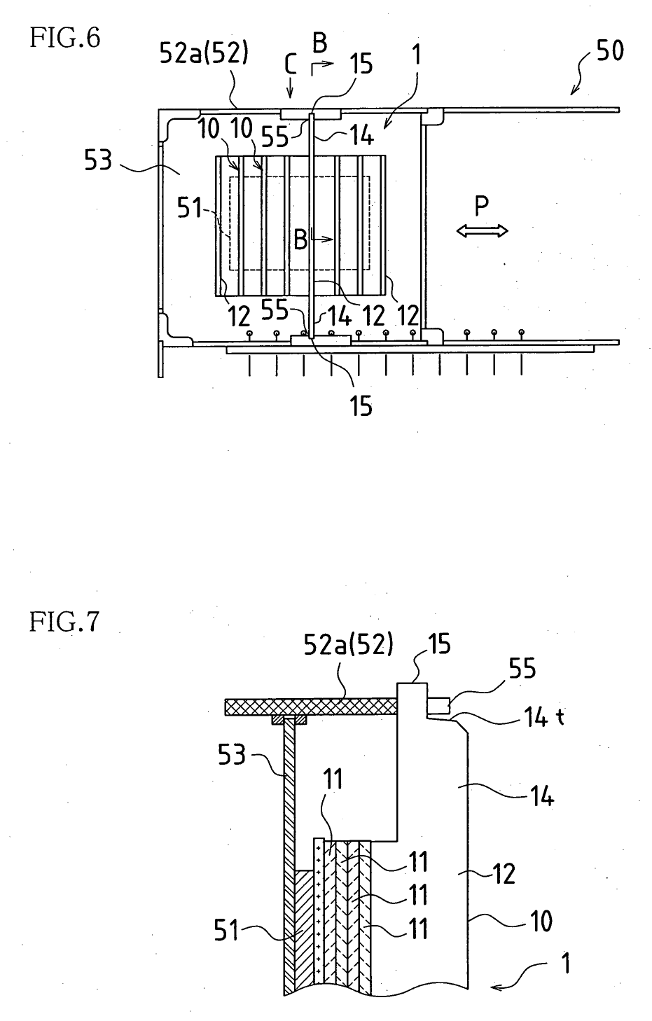

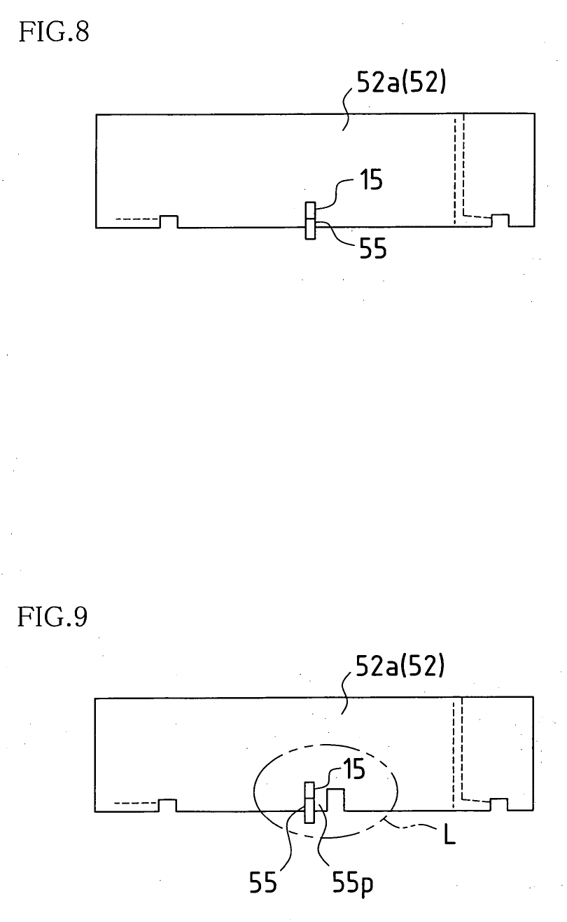

FIG. 6 is a top view of an electronic device in which the heat sink 1 according to Embodiment 1 of the present invention has been engaged to the case by the engaging portion. FIG. 7 is an enlarged cross-sectional view in which the engaging portion of the heat sink 1 in FIG. 6 is viewed from arrow B. FIG. 8 is a side view of the case of the electronic device equipped with the heat sink 1, viewed from arrow C in FIG. 6.

In the present example, the heat sink 1 is configured by disposing the heat dissipating members 10 such that the fin portions 12 are parallel to each other. Also, the extended portion 14 is formed by extending a fin portion 12 in a direction that intersects the juxtaposed placement direction P of the fin portions 12. The engaging portion 15 is formed in a convex shape in a tip end face 14t of the extended portion 14.

On the other hand, a concave-shaped catch portion 55 is formed in the side wall 52a of the case 52 at a position corresponding to the engaging portion 15. The convex-shaped engaging portion 15 is engaged to the concave-shaped catch portion 55. Thus, the heat sink 1 is held by being engaged to the case 52. As a result, the heat sink 1 does not separate from the electronic component 51.

In order to reliably engage the convex-shaped engaging portion 15 to the case 52, a protrusion that restrains the engaging portion 15 is provided adjacent to the concave-shaped catch portion 55 of the case 52.

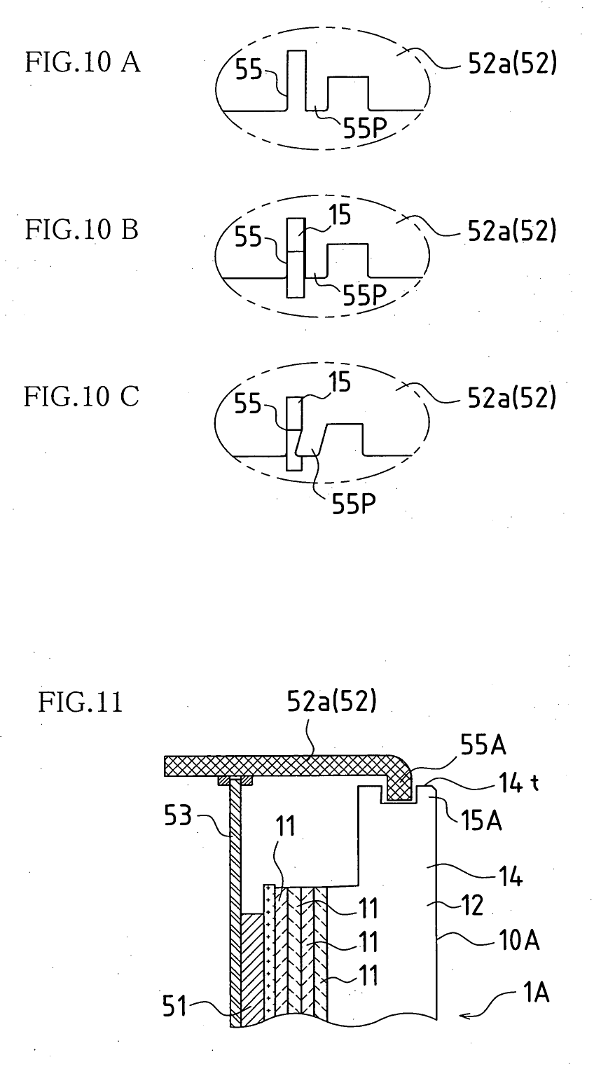

FIG. 9 is a side view of the case of the electronic device equipped with the heat sink 1 according to Embodiment 1 of the present invention, viewed from arrow C in FIG. 6. FIGS. 10A to 10C are enlarged views of an L portion in FIG. 9 in the electronic device equipped with the heat sink 1. FIG. 10A is a state diagram showing the engaging portion in an unengaged state, FIG. 10B is a state diagram showing the engaging portion in an engaged state, and FIG. 10C is a state diagram showing the engaging portion in a restrained state.

In the present example, the engaging portion 15 of the heat dissipating member 10 is formed in a convex shape in the tip end face 14t of the extended portion 14. On the other hand, a protrusion-like restraining portion 55p is formed beside the concave-shaped catch portion 55 in the side wall 52a of the case 52. The convex-shaped engaging portion 15, when in a state engaged to the concave-shaped catch portion 55 of the case 52, is firmly engaged to the case 52 by deforming the restraining portion 55p such that it presses against the engaging portion 15. Thus, the heat sink 1 is firmly held by the case 52. As a result, the heat sink 1 does not separate from the electronic component 51.

Following is a description of a heat sink 1A in which the engaging portion is formed in a concave shape, as a first modified example.

FIG. 11 is an enlarged cross-sectional view in which the engaging portion of the heat sink 1A according to the first modified example of Embodiment 1 of the present invention is viewed from arrow B in FIG. 6.

In this example, an engaging portion 15A of a heat dissipating member 10A is formed in a concave shape in the tip end face 14t of the extended portion 14. On the other hand, a convex-shaped catch portion 55A is formed in the side wall 52a of the case 52. The concave-shaped engaging portion 15A is engaged to the case 52 by engaging to the convex-shaped catch portion 55A of the case 52. Thus, the heat sink 1A is engaged to and held by the case 52. As a result, the heat sink 1A does not separate from the electronic component 51.

Following is a description of a heat sink 1B in which the engaging portion is formed in an L-shape, as a second modified example.

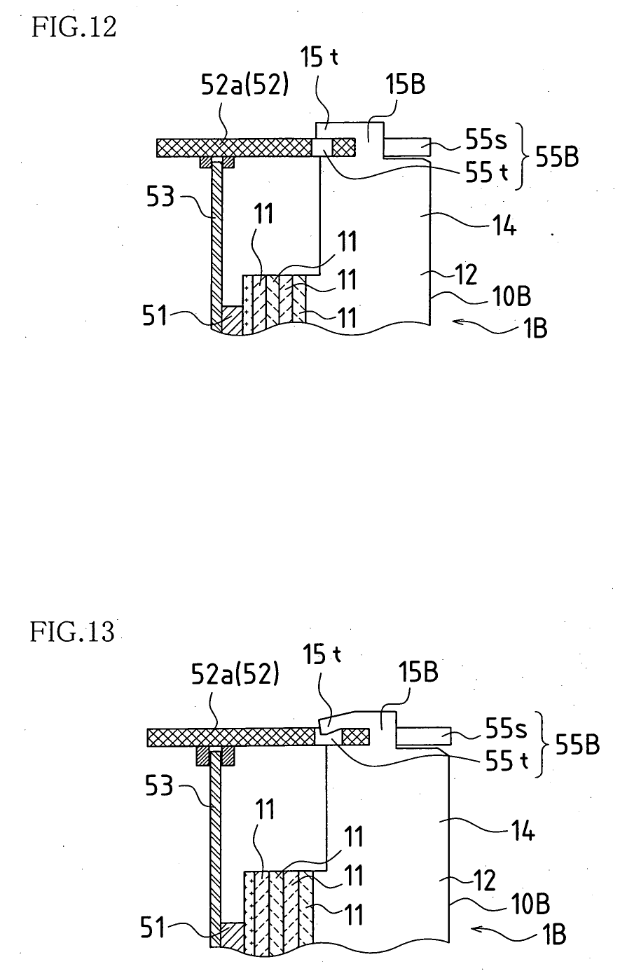

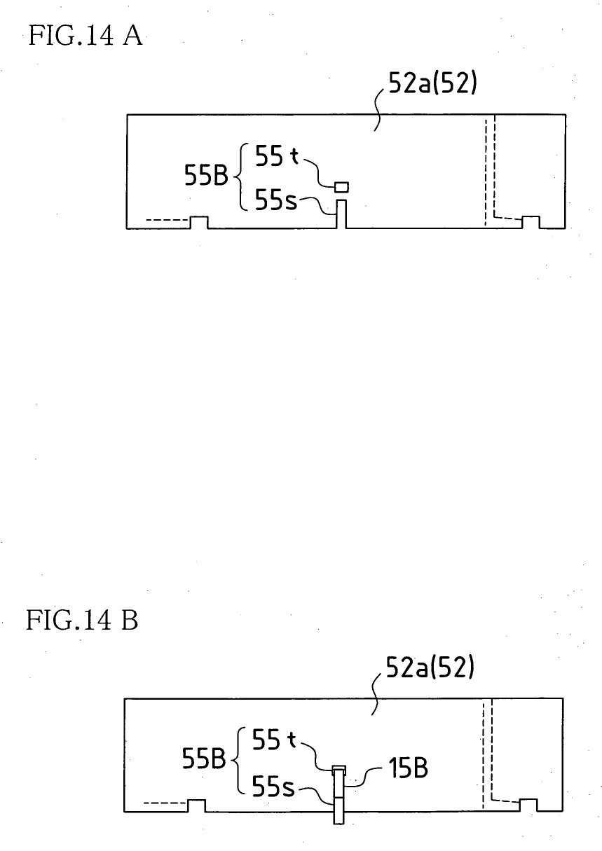

FIG. 12 is a cross-sectional view in which the engaging portion of the heat sink 1B according to the second modified example of Embodiment 1 of the present invention is viewed from arrow B in FIG. 6, in which the engaging portion is in an undeformed state. FIG. 13 is a cross-sectional view showing the engaging portion in FIG. 12 in a deformed state. FIGS. 14A and 14B are side views in which the case of the electronic device equipped with the heat sink 1B is viewed from arrow C in FIG. 6. FIG. 14A is a side view showing the catch portion in an unengaged state, and FIG. 14B is a side view showing the catch portion in an engaged state.

In this example, an engaging portion 15B of a heat dissipating member 10B is formed in an L shape. On the other hand, a catch portion 55B that engages with the L-shaped engaging portion 15B is formed in the side wall 52a of the case 52. The catch portion 55B is configured from a concave-shaped catch main portion 55s and an intruding portion 55t formed adjacent to the catch main portion 55s. The intruding portion 55t is formed as a depression deep enough that a tip 15t of the engaging portion 15B can fit in, or as a through-hole.

The L-shaped engaging portion 15B is engaged to the concave-shaped catch main portion 55s, and further is deformed such that the tip 15t fits into the intruding portion 55t. Thus, the heat sink 1B is firmly engaged to the case 52. As a result, the heat sink 1B does not separate from the electronic component 51.

Following is a description of a heat sink 1C in which the engaging portion is formed in a T shape, as a third modified example.

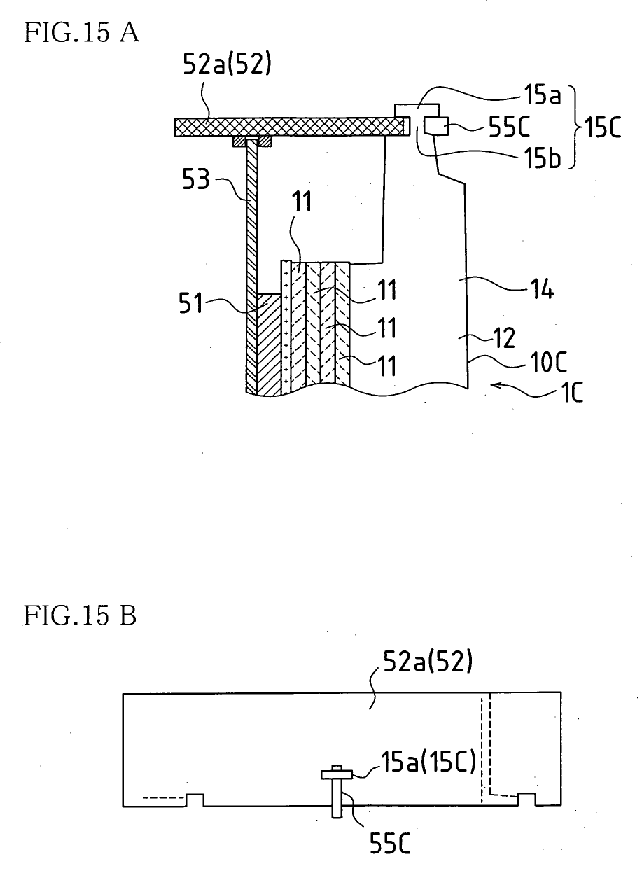

FIGS. 15A and 15B are illustrative diagrams that illustrate the engaging portion of the heat sink 1C according to the third modified example of Embodiment 1 of the present invention. FIG. 15A is a cross-sectional view in which the engaging portion is viewed before being deformed from arrow B in FIG. 6, and FIG. 15B is a side view in which the engaging portion is viewed after being deformed from arrow C in FIG. 6.

In the present example, an engaging portion 15C of a heat dissipating member 10C is formed in a T shape. Specifically, the engaging portion 15C is configured by forming a narrow neck portion 15b in the end of the extended portion 14, and further forming a tip head portion 15a in that end that is wider than the neck portion 15b. The width of the neck portion 15b is determined such that the tip head portion 15a can easily be twisted with needle-nose pliers or the like.

On the other hand, a concave-shaped catch portion 55C into which the T-shaped engaging portion 15C can be inserted is formed in the side wall 52a of the case 52. The concave-shaped catch portion 55C is a notch with a width into which the T-shaped engaging portion 15C can be inserted, and is formed with a width such that the tip head portion 15a cannot be removed from the catch portion 55C when the tip head portion 15a has been twisted. Specifically, the catch portion 55C is a rectangular notch that has about the same width as the plate thickness of the T-shaped engaging portion 15C.

The T-shaped engaging portion 15C is engaged to the case 52 by being inserted in the catch portion 55C and also twisting the tip head portion 15a. Thus, the heat sink 1C is firmly engaged to the case 52. As a result, the heat sink IC does not separate from the electronic component 51.

Following is a description of a heat sink ID in which a contact face is formed as the engaging portion, as a fourth modified example.

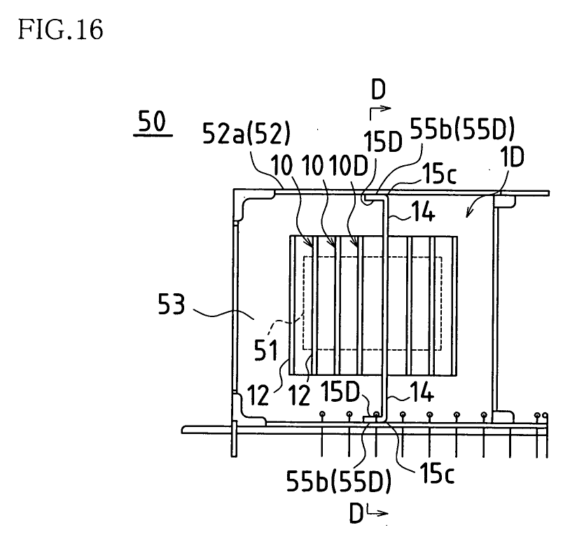

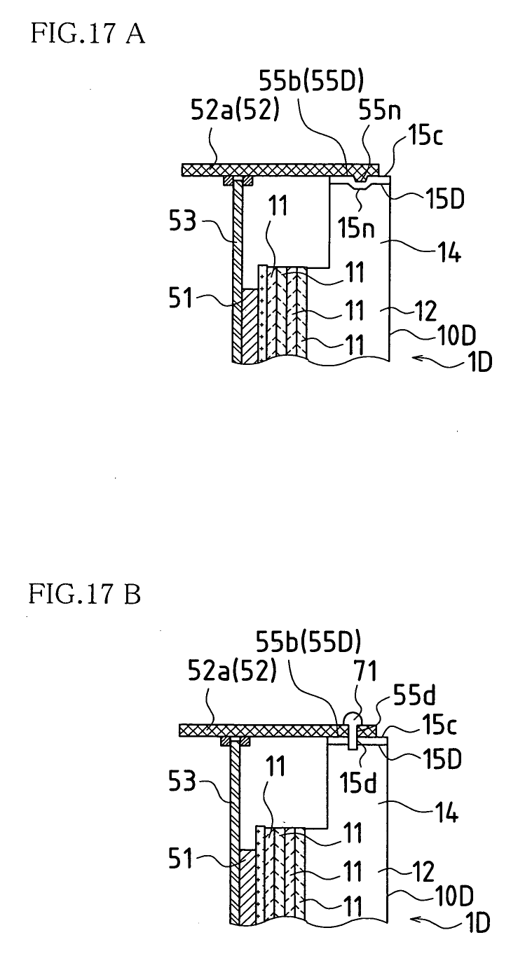

FIG. 16 is a top view of the electronic device in which the heat sink 1D according to the fourth modified example of Embodiment 1 of the present invention has been engaged to the case by the engaging portion. FIGS. 17A and 17B are cross-sectional views in which the engaging portion of the heat sink 1D is viewed from arrow D in FIG. 16. FIG. 17A is a cross-sectional view of a mode in which a concave portion is provided in the contact face as the engaging portion, and FIG. 17B is a cross-sectional view of a mode in which the contact face as the engaging portion is fixed to the case with a screw.

In the present example, an engaging portion 15D of a heat dissipating member 10D is formed in a flat shape by bending the extended portion 14 approximately 90 degrees. The face formed by bending the extended portion 14 by 90 degrees is a contact face 15c that makes contact with the side wall 52a of the case 52. Also, contact faces 15c used as the engaging portion 15D are formed on both sides of the extension direction of the fin portion 12.

On the other hand, a contact portion 55b used as a catch portion 55D that presses against the contact faces 15c is provided in the side wall 52a of the case 52. The contact portion 55b is formed in a flat shape, and its face makes contact with the contact faces 15c.

The contact faces 15c formed on both sides of the fin portion 12 are pressed against by the contact portions 55b, from both sides. Thus, because the fin portion 12 is pressed against from both sides, the heat sink 1D is stably fixed.

Also, a configuration may be adopted in which a concave portion 15n is formed in the contact face 15c, and on the other hand, a convex portion 55n is formed in the contact portion 55b and the concave portion 15n and the convex portion 55n fit together (see FIG. 17A). Because the concave portion 15n and the convex portion 55n fit together and are engaged with each other, the heat sink 1D is more stably fixed. A configuration may also be adopted in which a convex portion is formed in the contact face 15c, and a concave portion is formed in the contact portion 55b.

Also, a configuration may be adopted in which a contact face through-hole 15d is formed in the contact face 15c, and on the other hand, a contact portion through-hole 55d is formed in the contact portion 55b used as the catch portion 55, a screw 71 is inserted in the contact face through-hole 15d and the contact portion through-hole 55d, joining them together (see FIG. 17B). Thus, the heat sink 1D is fixed to the case 52 by the screw 71, and therefore firmly fixed to the case 52.

In the above embodiments, configurations were disclosed by way of example in which, as the heat sinks 1 and 1A to 1D, the extended portion 14 was formed by extending in only one direction relative to the juxtaposed placement direction P of the fin portions 12, but the direction in which the extended portion 14 is formed is not limited to this configuration. For example, the heat sink 1 may also be configured by extending a fin portion 12 in both the juxtaposed placement direction P of the fin portion 12 and a direction that intersects the juxtaposed placement direction P.

Thus, it is possible to engage an engaging portion to the constituent members (the case 52 and the mounting substrate 53, see FIG. 1) of the electronic device 50 present in a direction that intersects the juxtaposed placement direction P of the fin portions 12, and to engage the engaging portions 15 and 15A to 15D to the constituent members (the case 52 and the mounting substrate 53) of the electronic device 50 present in the juxtaposed placement direction P of the fin portions 12. As a result, the heat sinks 1 and 1A to 1D are held more stably.

### Embodiment 2

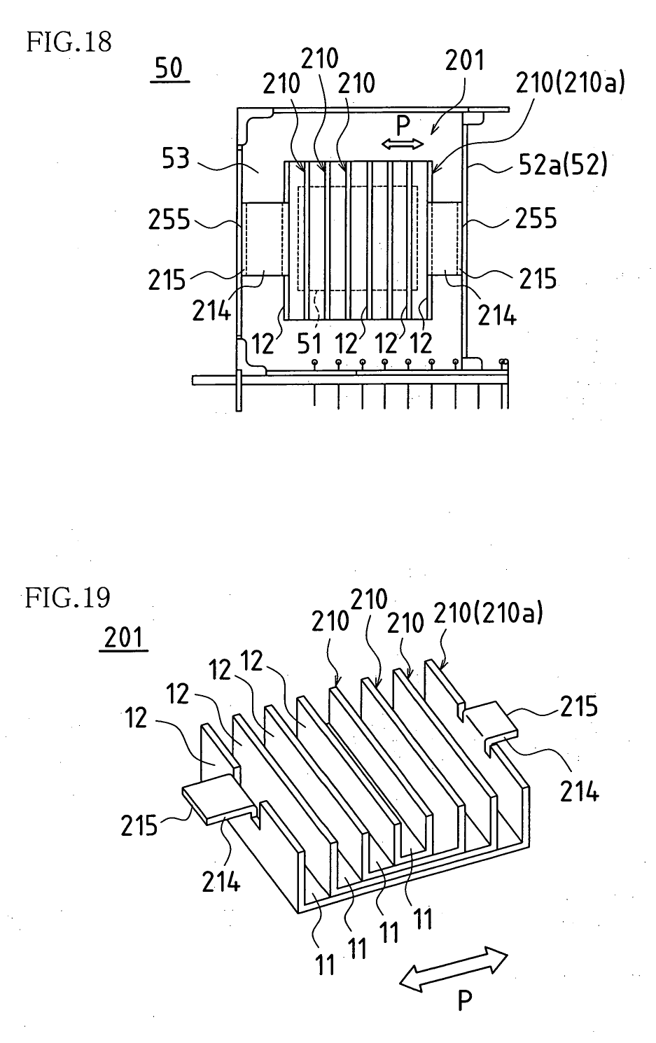

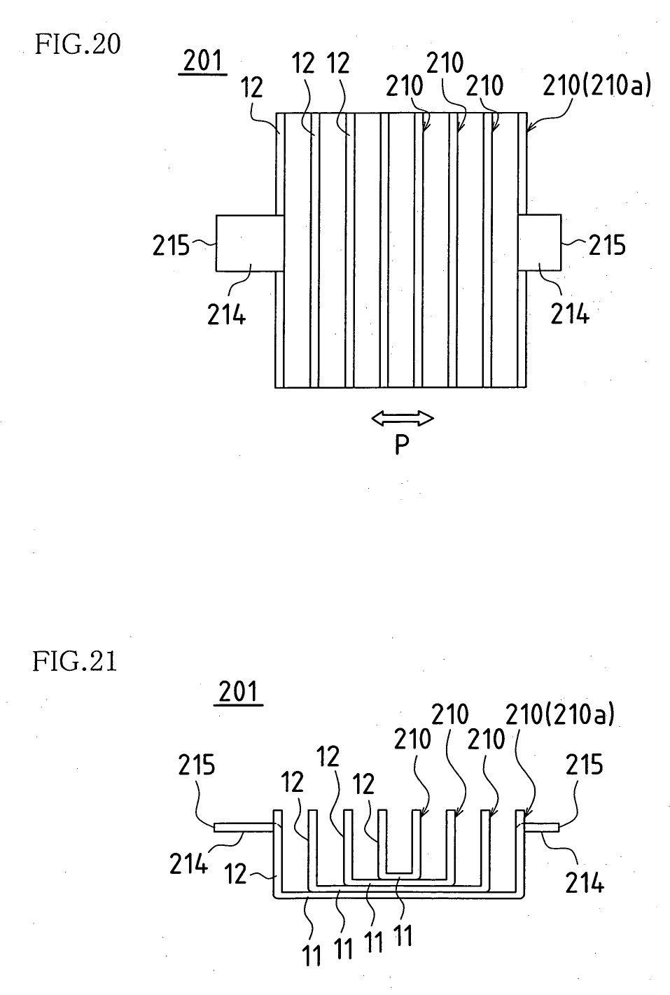

FIG. 18 is a top view in which an electronic device equipped with a heat sink 201 according to Embodiment 2 of the present invention is viewed from above. FIG. 19 is a perspective view of the heat sink 201 viewed obliquely from above. FIG. 20 is a top view of the heat sink 201 viewed from above. FIG. 21 is a side view of the heat sink 201.

The heat sink 201 according to the present embodiment is assembled by stacking a plurality of heat dissipating members 210 at the main body portions 11. This sort of configuration is similar to Embodiment 1, and so its description is omitted here. Also, the specific structure of the heat dissipating members 210 is approximately similar to Embodiment 1, and so a description thereof is omitted here.

Here, the extension direction of an extended portion 214 differs, and so this point will be described.

The extended portion 214 is formed by extending the fin portion 12 in a heat dissipating member 210 selected as desired. The extended portion 214 is formed by extending in the juxtaposed placement direction P of the fin portions 12. Specifically, the extended portion 214 is formed such that it reaches from the fin portion 12 of a heat dissipating member 210a, which has been disposed furthest outside among the heat dissipating members 210, to the side wall 52a of the case 52.

An engaging portion 215 is formed in the tip of the extended portion 214, in a shape that engages a catch portion 255 of the case 52. Due to the engaging portion 215 engaging to the catch portion 255 of the case 52, the heat sink 1 is held by and fixed to the electronic device 50. Thus, the heat sink 201 does not separate from the electronic component 51. The example of the engaging portion 15 in Embodiment 1 is applied as the specific mode of the engaging portion 215, and so its description is omitted here.

### Embodiment 3

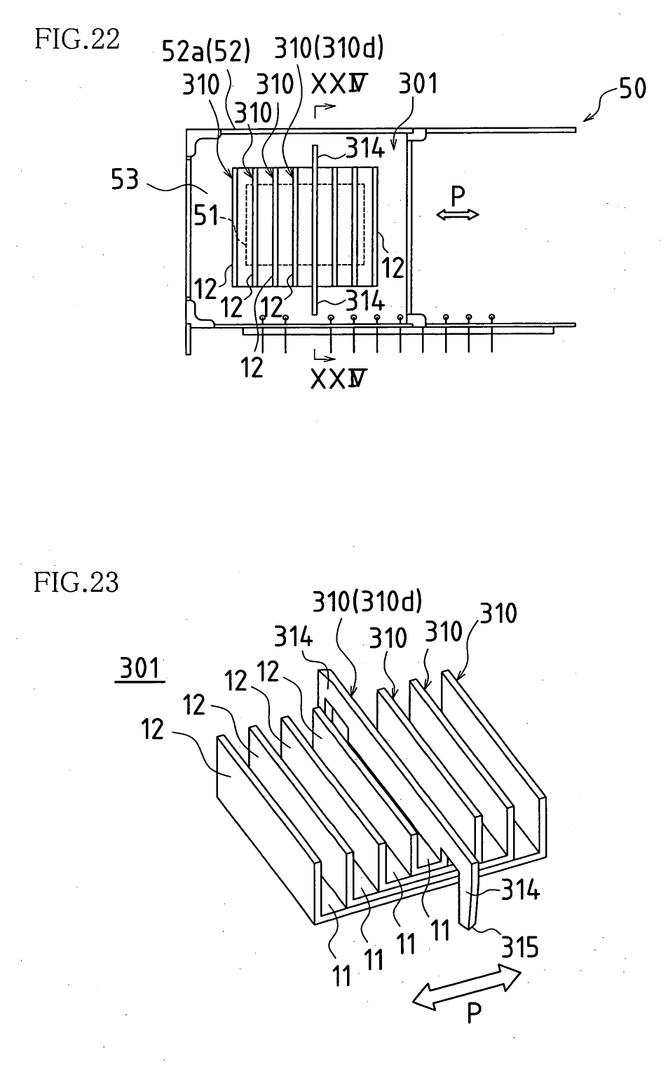

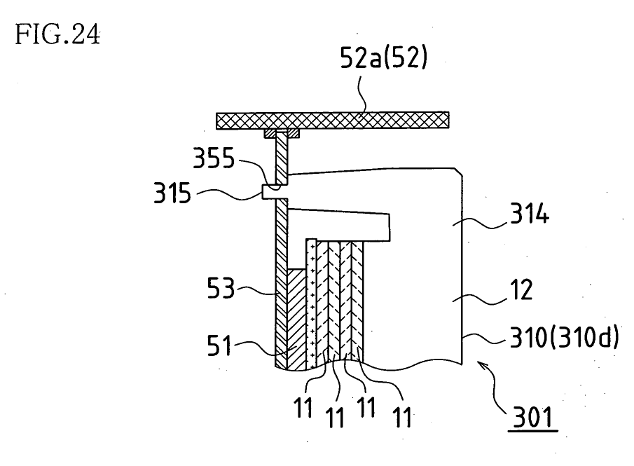

FIG. 22 is a top view in which the electronic device equipped with a heat sink 301 according to Embodiment 3 of the present invention is viewed from above. FIG. 23 is a perspective view of the heat sink 301 viewed obliquely from above. FIG. 24 is a cross-sectional view of the engaging portion of the heat sink 301 viewed from arrow XXIV.

The heat sink 301 according to the present embodiment is assembled by stacking a plurality of heat dissipating members 310 at the main body portions 11. This sort of configuration is similar to Embodiment 1, and so its description is omitted here. Also, the specific structure of the heat dissipating members 310 is approximately similar to Embodiment 1, and so its description is omitted here.

Here, the extension direction of an extended portion 314 differs, and so this point will be described.

The extended portion 314 is formed by extending the fin portion 12 in a heat dissipating member 310 selected as desired. The extended portion 314 is formed by extending in a direction perpendicular to the juxtaposed placement direction P of the fin portions 12, and by bending and extending such that the extended portion 314 reaches the mounting substrate 53. Specifically, the extended portion 314 is formed in the fin portion 12 of a heat dissipating member 310d, which is the heat dissipating member among the heat dissipating members 310 that has been stacked uppermost, such that the extended portion 314 reaches the mounting substrate 53.

An engaging portion 315 is formed in the tip of the extended portion 314, in a shape that engages a catch portion 355 of the mounting substrate 53. Due to the engaging portion 315 engaging the mounting substrate 53, the heat sink 301 is held by and fixed to the electronic device 50. Thus, the heat sink 301 does not separate from the electronic component 51.

Also, because the heat sink 301 makes contact with the mounting substrate 53, the heat transmitted from the electronic component 51 to the mounting substrate 53 can be dissipated from the heat sink 301. And, by joining the engaging portion 315 of the heat sink 301 to the mounting substrate 53 by soldering or the like, the heat dissipating effect can be improved.

The example of the engaging portion 15 in Embodiment 1 is applied as the specific mode of the engaging portion 315, and so its description is omitted here.

### Embodiment 4

A heat sink 401 according to the present embodiment has the similar structure to the heat sinks according to Embodiments 1 (including the modified examples, same below) to 3. That is, the heat sink 401 is configured with heat dissipating members 410a to 410d (below, referred to together as “heat dissipating members 410” where necessary) stacked at the main body portions 11. Also, the extended portion 14 is provided in at least one of the heat dissipating members 410, and the engaging portion 15 is formed in the tip of the extended portion 14. The description of the constituent elements is similar to Embodiments 1 to 3, and therefore is omitted here.

Here, a position-matching structure of the heat dissipating members 410 is described.

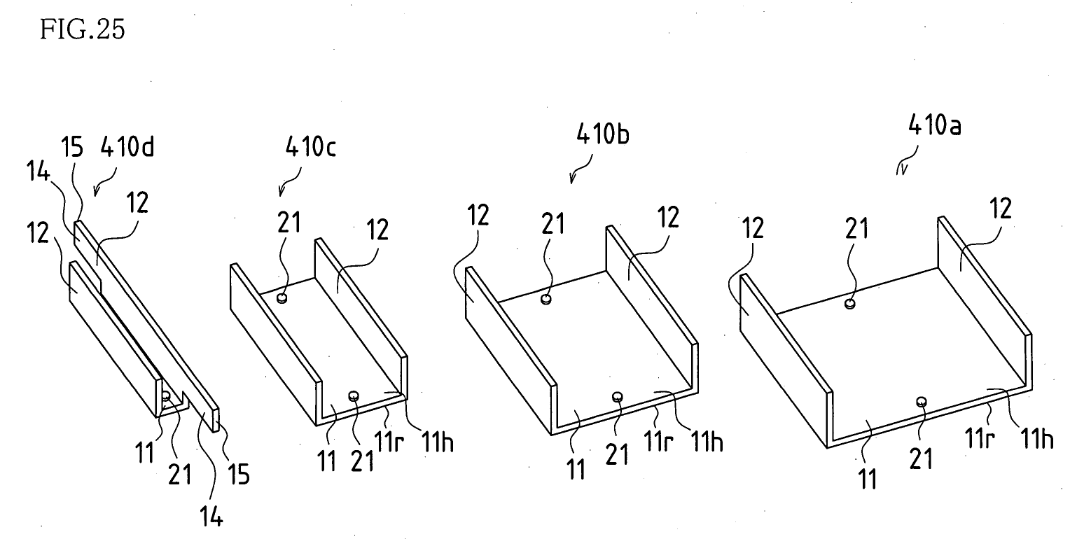

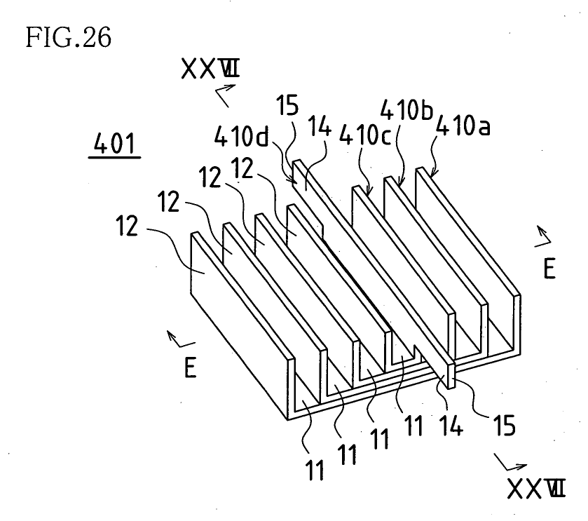

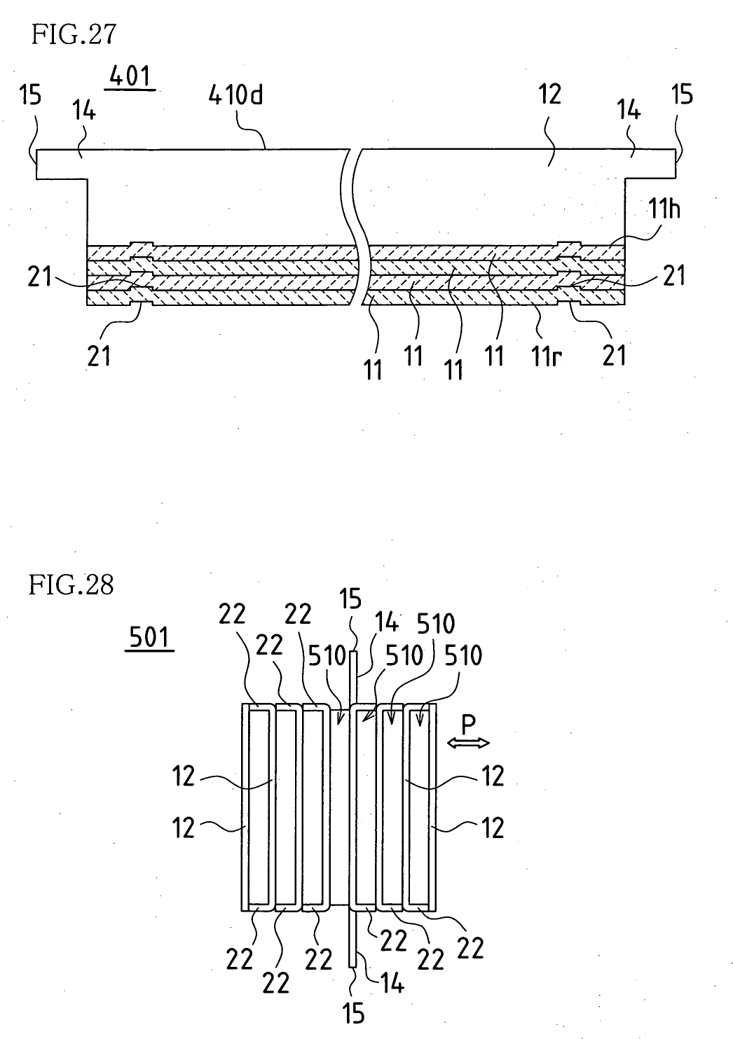

FIG. 25 is a separated view in which the heat sink 401 according to Embodiment 4 of the present invention is separated into the heat dissipating members 410a to 410d. FIG. 26 is a perspective view in which the heat sink 401 is viewed obliquely from above. FIG. 27 is a cross-sectional view of the heat sink 401 viewed from arrow XXVII in FIG. 26.

In the main body portion 11 of each heat dissipating member 410, fitting portions 21 that fit together when stacking the main body portions 11 are formed in a front face side 11h and a back face side 11r. The fitting portion 21 of the front face side 11h and the fitting portion 21 of the back face side 11r are formed with dimensions such that they fit together. Specifically, the fitting portion 21 of the front face side 11h is formed convexly with an approximately columnar shape, and the fitting portion 21 of the back face side 11r is formed concavely with an approximately columnar shape. The fitting portions 21 are not limited to a convex or concave shape. For example, they may be formed with an approximately rectangular protrusion used as the fitting portion 21 of the front face side 11h, and an approximately lengthwise depression used as the fitting portion 21 of the back face side 11r, with dimensions such that the fitting portions 21 fit together.

Also, two of the fitting portions 21 are formed in the main body portion 11 and disposed separated from each other. Thus, little displacement occurs when stacking the heat dissipating members 410. The separation distance is preferably made the same in each heat dissipating member 410. Thus, it is possible to match the positions of the heat dissipating members 410 with each other regardless of the type selected. That is, because fittingly optimum heat dissipating members 410 can be selected and combined, it is possible to manufacture a heat sink 401 that has an optimum heat dissipating capacity.

### Embodiment 5

A heat sink 501 according to the present embodiment has the similar structure to the heat sinks according to Embodiments 1 to 3. That is, the heat sink 501 is configured by stacking heat dissipating members 510 at the main body portions 11. Also, the extended portion 14 is provided in at least one of the heat dissipating members 510, and the engaging portion 15 is formed in the tip of the extended portion 14. The description of the constituent elements is similar to Embodiments 1 to 3, and therefore is omitted here.

Here, a position-matching structure of the heat dissipating members 510 that differs from that in Embodiment 4 is described.

FIG. 28 is a top view in which the heat sink 501 according to Embodiment 5 of the present invention is viewed from above.

The heat dissipating members 510 that configure the heat sink 501 are stacked such that the fin portions 12 are approximately parallel. Also, the heat dissipating members 510 are configured with a positioning portion 22 formed at both ends of the fin portion 12, such that the heat dissipating members 510 are positioned with the fin portions 12 disposed at predetermined intervals in the juxtaposed placement direction P.

The positioning portions 22 are formed by extending both ends of the fin portions 12 and bending them approximately 90 degrees to the outside. Also, the positioning portions 22 formed on both ends to become pairs are formed such that they have approximately equal length.

The heat dissipating members 510 are assembled by placing the positioning portions 22 in contact with the adjacent fin portions 12. Thus, the adjacent fin portions 12 are disposed approximately parallel. That is, a constant gap between the adjacent fin portions 12 is insured, fixing the position of the main body portion 11.

Also, the positioning portions 22 have a function to set the distance to an adjacent fin portion 12, and so it is possible to modify the arrangement of the heat dissipating members 510 by changing the length of the positioning portions 22.

### Embodiment 6

A heat sink 601 according to the present embodiment has the similar structure to the heat sinks according to Embodiments 1 to 3. That is, the heat sink 601 is configured by stacking heat dissipating members 610 at the main body portions 11. Also, the extended portion 14 is provided in at least one of the heat dissipating members 610, and the engaging portion 15 is formed in the tip of the extended portion 14. The description of the constituent elements is similar to Embodiments 1 to 3, and therefore is omitted here. The positioning structure in Embodiments 4 and 5 may be adopted in the heat sink 601 according to the present embodiment.

Here, a description of the joining structure of the heat dissipating members 610 is given by way of example.

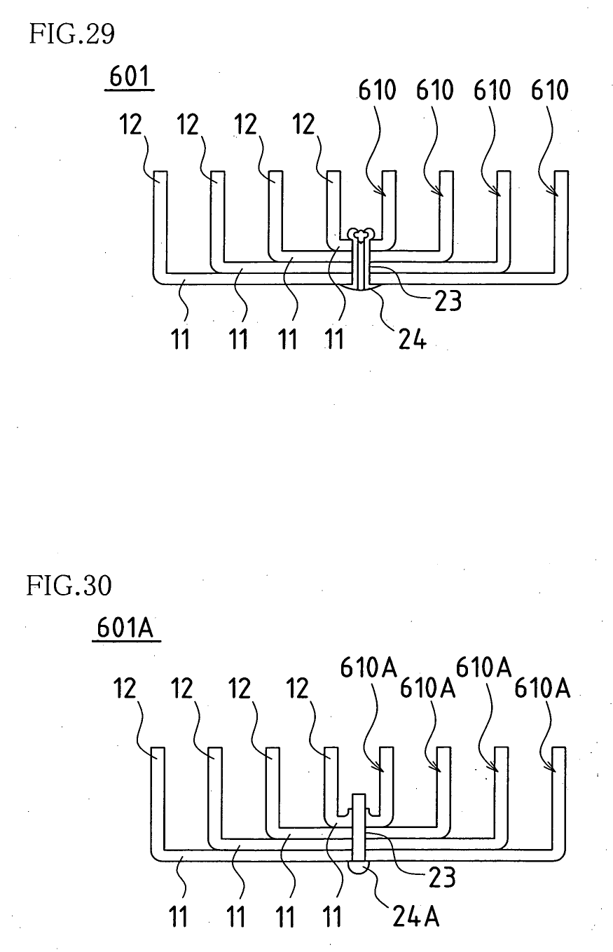

FIG. 29 is a cross-sectional view of the heat sink 601 according to Embodiment 6 of the present invention, viewed from arrow E in FIG. 26.

In the heat dissipating members 610, a through-hole 23 for joining is formed in the main body portion 11. The through-hole 23 is formed to be a hole that passes through the heat dissipating members 610 when they are stacked. By inserting a joining member 24 in the hole that passes through and deforming the tip of the joining member 24, the heat dissipating members 610 are joined. Alternatively, the heat dissipating members 610 are joined by pressing in a joining member 24 having approximately the same cross-section as the single-body through-hole.

Specifically, in each heat dissipating member 610, a column-shaped through-hole 23 with approximately the same radius is formed in approximately the center of the main body portion 11. Also, the through-holes 23 are disposed at a position that they form a hole that passes through the heat dissipating members 610 when the respective heat dissipating members 610 are stacked. By inserting a blind rivet (joining member 24) in this column-shaped hole that passes through the heat dissipating members 610 and riveting with a riveter, the heat dissipating members are joined. Thus, a plurality of the heat dissipating members 610 can be joined in one operation. Also, because the tip of the joining member 24 is plastic-deformed, the heat dissipating members 610 do not separate. A screw or the like may also be used as the joining member 24.

FIG. 30 is a cross-sectional view in which a heat sink 601A according to a modified example of Embodiment 6 of the present invention is viewed from arrow E in FIG. 26.

Heat dissipating members 610A are joined by pressing in a screw with approximately the same radius as a column-shaped through-hole. Thus, the heat dissipating members 610A can easily be joined.

Alternatively, a bolt (male joining component, not shown) and a nut (fitting component, not shown) may be used as a joining member 24A. Specifically, the heat dissipating members 610A are joined at the main body portions 11 by inserting the bolt into the column-shaped through-hole and fitting the tip of the bolt into the nut. Thus, because the male joining component and the fitting component can be removed even after joining a plurality of the heat dissipating members 610A and forming the heat sink 601A, it is possible to modify one heat dissipating member 610A to another heat dissipating member 610A. Thus, it is possible to easily modify the heat dissipating capacity.

### Embodiment 7

A heat sink 701 according to the present embodiment has the similar structure to the heat sinks according to Embodiments 1 to 3. That is, the heat sink 701 is configured by stacking heat dissipating members 710 at the main body portions 11. Also, the extended portion 14 is provided in at least one of the heat dissipating members 710, and the engaging portion 15 is formed in the tip of the extended portion 14. The description of the constituent elements is approximately similar to Embodiments 1 to 3, and therefore is omitted here. The positioning structure in Embodiments 4 and 5 may be adopted in the heat sink 701 according to the present embodiment.

Here, a description of the joining structure of the heat dissipating members 710 that differs from that in Embodiment 6 is described. Also, the heat dissipating members 710 of the present embodiment differ at some points from the heat sinks according to Embodiments 1 to 3, and so those points will be described.

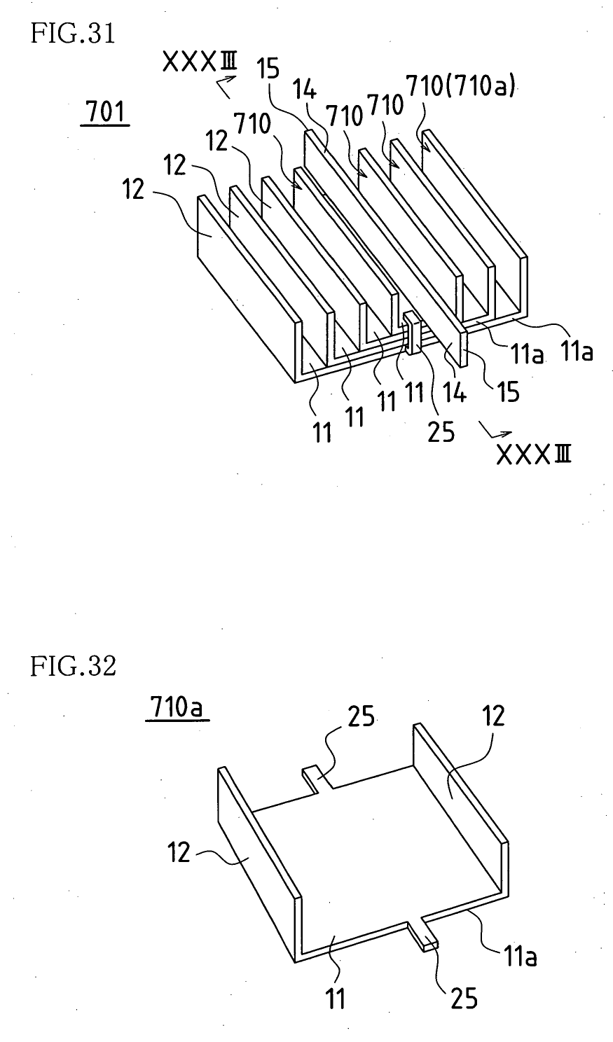

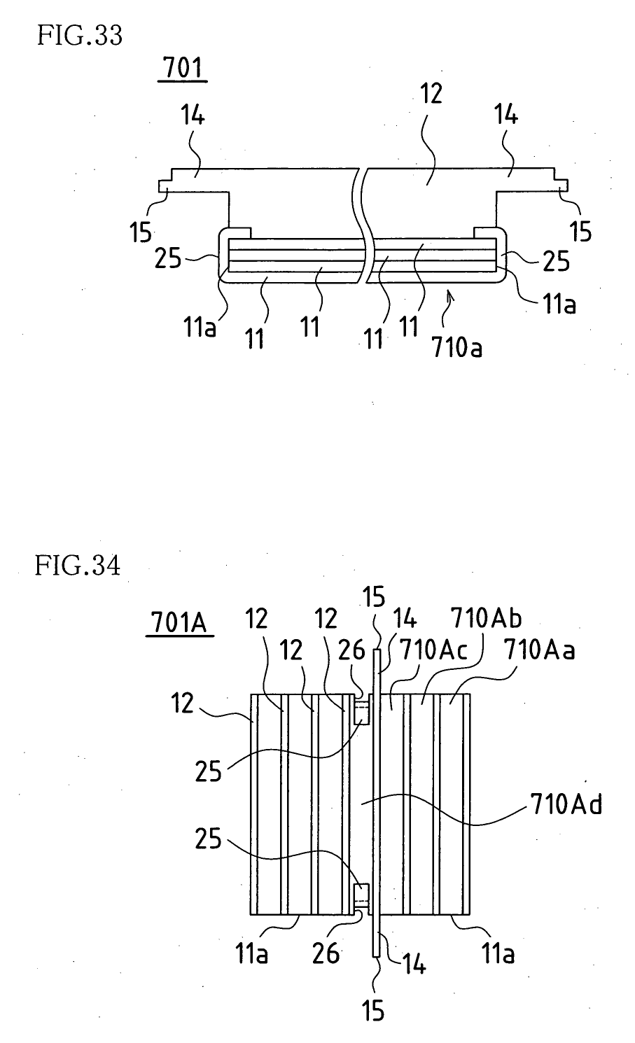

FIG. 31 is a perspective view of the heat sink 701 according to Embodiment 7 of the present invention viewed obliquely from above. FIG. 32 is a perspective view of a heat dissipating member furthest outside in the heat sink 701, viewed obliquely from above. FIG. 33 is a cross-sectional view of the heat sink 701 viewed from arrow XXXIII in FIG. 31.

The heat dissipating members 710 according to Embodiment 7 are formed such that the length of the main body portions 11 are approximately equal, such that end faces 11a of the main body portions 11 are even. The heat dissipating members 710 are stacked such that the end faces 11a of the main body portions 11 form one face.

A heat dissipating member 710a, which is the heat dissipating member furthest outside, is formed with a protruding portion 25, for causing the stacked main body portions 11 to be joined by pressing against each other, protruding in the end face 11a of the main body portion 11. The protruding portion 25 is bent so that it makes contact with the end faces 11a of the stacked main body portions 11, and so that it pushes against the main body portion 11 of the heat dissipating member 710 that has been stacked uppermost. Thus, the heat dissipating members 710 are joined.

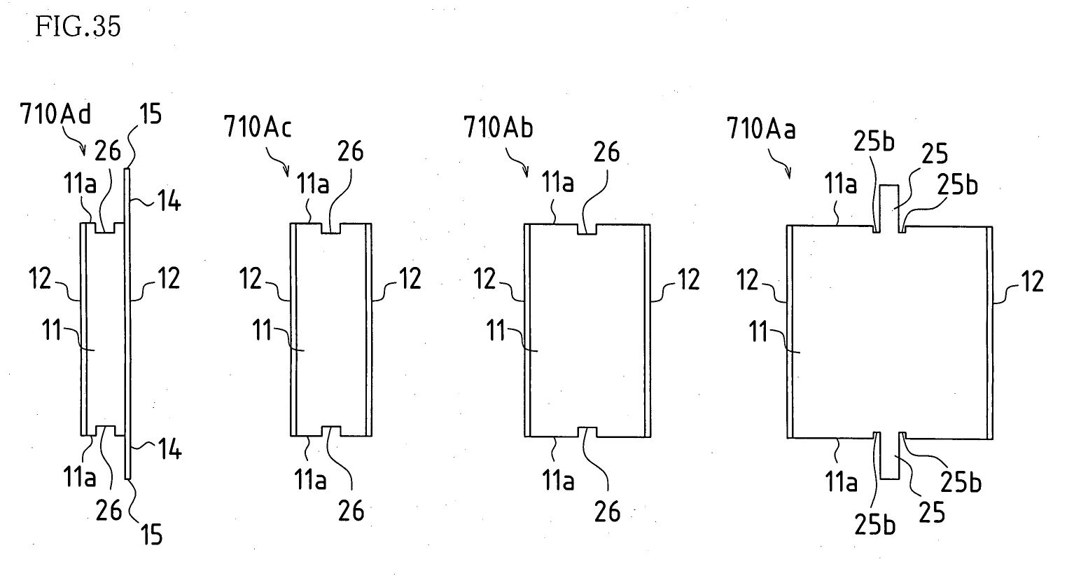

FIG. 34 is a top view of a heat sink 701A with a structure in which it is positioned by the protruding portion, as a first modified example of Embodiment 7 of the present invention. FIG. 35 is an exploded view in which the heat sink 701A is exploded.

A heat dissipating member 710Aa disposed furthest outside of heat dissipating members 710Aa to 710Ad is formed with the protruding portion 25 protruding in the end face 11a of the main body portion 11. The protruding portion 25 causes the stacked main body portions 11 to be joined by pressing against each other. A notch 25b is formed on both sides of the base of the protruding portion 25. Thus, the bend of the protruding portion 25 is performed inside relative to the end face 11a of the main body portion 11, and so a protrusion of the thickness of the protruding portion 25 is eliminated from the end face 11a.

Also, in the other heat dissipating members 710Ab to 710Ad to be joined by the protruding portion 25, a concave-shaped fitting concave portion 26 is formed in the both end faces 11a of the main body portion 11. The protruding portion 25 fits into the fitting concave portion 26.

That is, in a state with the heat dissipating members 710Ab to 710Ad stacked and the fitting concave portions 26 made approximately uniform, by further bending the protruding portions 25 after stacking the heat dissipating member 710Aa, it is possible to join the heat dissipating members 710Aa to 710Ad in a state with the positions of the heat dissipating members 710Aa to 710Ad matched.

Thus, matching the positions of the heat dissipating members 710Aa to 710Ad and joining the heat dissipating members 710Aa to 710Ad can be performed as a series of operations. Also, because all or a part of the protruding portion 25 is buried under the end face 11a, protrusion from the end face 11a is eliminated (or reduced).

Also, the fitting concave portion 26 may be configured by providing a pair of positioning projections in the main body portion 11.

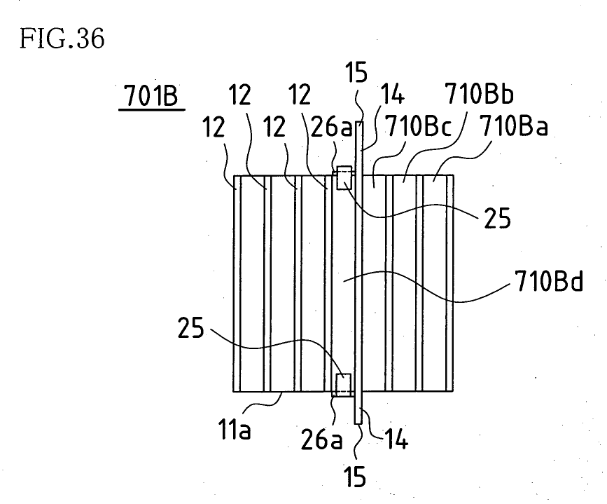

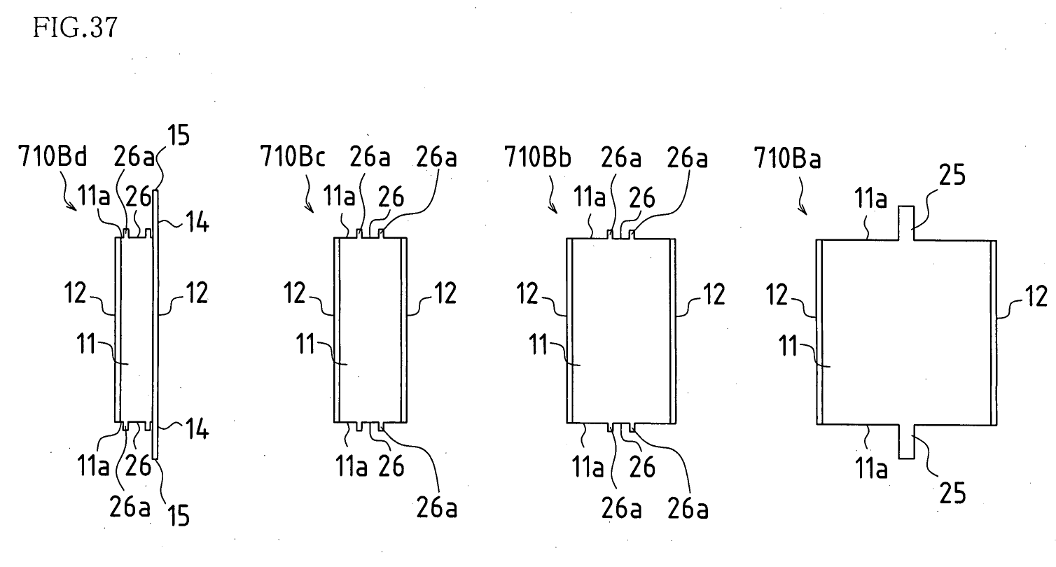

FIG. 36 is a top view of a heat sink 701B with another structure in which it is positioned by the protruding portion, as a second modified example of Embodiment 7 of the present invention. FIG. 37 is an exploded view in which the heat sink 701B is exploded.

A heat dissipating member 710Ba, which is the furthest outside of heat dissipating members 710Ba to 710Bd, is formed with protruding portions 25 protruding in the end face 11a of the main body portion 11. The protruding portions 25 cause the main body portions 11 that have been stacked to be joined by pressing against each other.

In the other heat dissipating members 710Bb to 710Bd to be joined by the protruding portion 25, a pair of positioning protrusions 26a are formed in both end faces 11a of the main body portions 11. The gap between the pair of positioning protrusions 26a is a distance such that the protruding portions 25 fit together with the positioning protrusions 26a.

That is, in a state with the heat dissipating members 710Bb to 710Bd stacked and the fitting concave portions 26 made approximately uniform, by further bending the protruding portions 25 after stacking the heat dissipating member 710Ba, the heat dissipating members 710Ba to 710Bd are joined in a state with the positions of the heat dissipating members 710Ba to 710Bd matched. Thus, matching the positions of the heat dissipating members 7101Ba to 710Bd and joining the heat dissipating members 710Ba to 710Bd can be performed as a series of operations.

### Embodiment 8

A heat sink 801 according to the present embodiment has the similar structure to the heat sinks according to Embodiments 1 to 3. That is, the heat sink 801 is configured by stacking the heat dissipating members 10 at the main body portions 11. Also, the extended portion 14 is provided in at least one of the heat dissipating members 10, and the engaging portion 15 is formed in the tip of the extended portion 14. The description of the constituent elements is similar to Embodiments 1 to 3, and therefore is omitted here. The positioning structure in Embodiment 4 or 5 may be adopted in the heat sink 801 according to the present embodiment.

Here, a description of the joining structure of the heat dissipating members 10 is given by way of example. Also, the joining structure of Embodiments 6 or 7 may be used together.

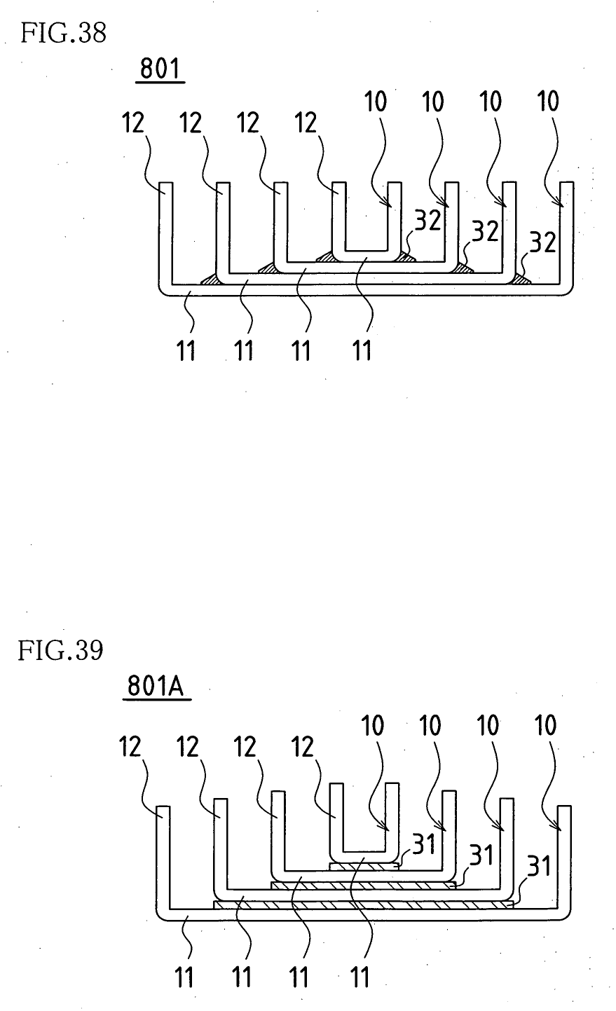

FIG. 38 is a cross-sectional view in which the heat sink 801 according to Embodiment 8 of the present invention is viewed from arrow E in FIG. 26. The heat dissipating members 10 are fixed by welding fixing portions 32 on the base of the main body portions 11. Thus, it is possible to firmly join the heat dissipating members 10. The heat dissipating members may also be configured using tin plate or copper as the heat dissipating members 10 and joined by soldering. Thus, it is possible to assemble and join the heat dissipating members 10 using a soldering iron with which work is easy to perform.

A configuration may also be adopted in which only the heat dissipating member 10 having the engaging portion 15 is formed from tin plate, and the remaining heat dissipating members 10 are formed from aluminum. Thus, the heat sink 801 can be lightened and the portions that have been engaged to the case can be easily soldered.

Also, copper, which has a high thermal conductivity ratio, may be adopted only in a heat dissipating member 10a that is furthest outside (see FIG. 31). Thus, it is possible to improve the heat dissipating efficiency of the heat sink 801.

FIG. 39 is a cross-sectional view in which a heat sink 801A according to a modified example of Embodiment 8 of the present invention is viewed from arrow E in FIG. 26. The heat dissipating members 10 are fixed by thermally conductive adhesive 31 on the base of the main body portions 11. Thus, it is possible to easily join the heat dissipating members 10. Also, the heat dissipating members 10 may be adhered using two-sided tape instead of the thermally conductive adhesive 31. Thus, preparations for the adhesive work can be simplified, and it is possible to more easily join the heat dissipating members 10.

A configuration may also be adopted in which the heat dissipating members 10 are joined by combining any of the methods of joining with the thermally conductive adhesive 31 or two-sided tape, joining with the joining member 24 disclosed in Embodiment 6, and joining with the protruding portions 25 disclosed in Embodiment 7.

### Embodiment 9

A heat sink 901 according to the present embodiment has the similar structure to the heat sinks according to Embodiments 1 to 3. That is, the heat sink 901 is configured by stacking the heat dissipating members 910 at the main body portions 11. Also, the extended portion 14 is provided in at least one of the heat dissipating members 910, and the engaging portion 15 is formed in the tip of the extended portion 14. The description of the constituent elements is similar to Embodiments 1 to 3, and therefore is omitted here. The positioning structure in Embodiment 4 or 5 may be adopted. Also, the joining structures of Embodiments 6 to 8 may be adopted.

Here, a description of a structure for achieving an improvement in the heat dissipation of the heat sink 901 is given by way of example.

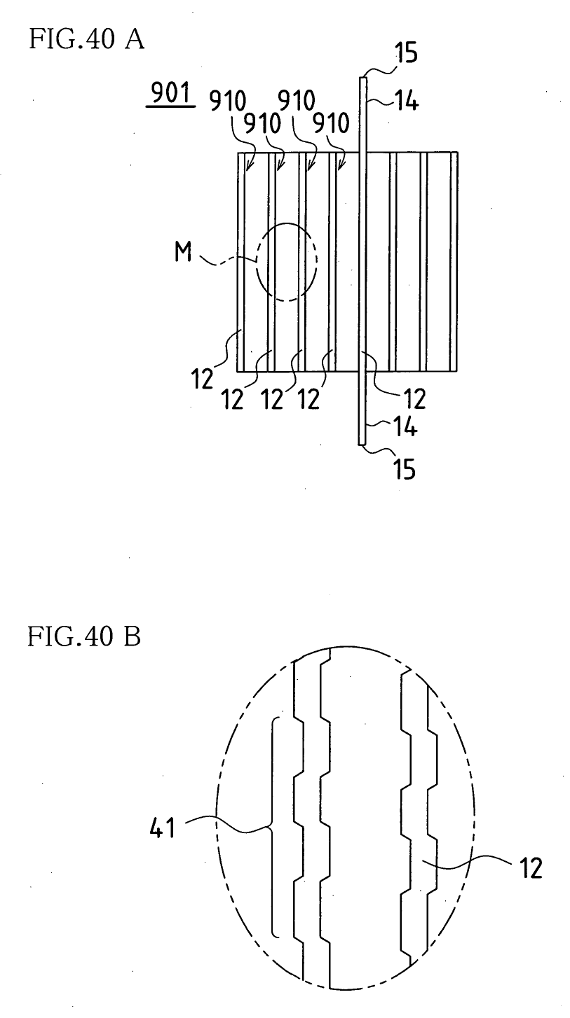

FIGS. 40A and 40B show the heat sink 901 according to Embodiment 9 of the present invention. FIG. 40A is a top view in which the heat sink 901 is viewed from above, and FIG. 40B is an enlarged view of a portion M.

In the heat dissipating members 910, many convexo-concaves 41 are formed in the fin portions 12. By densely forming the convexo-concaves 41, the surface area of the fin portion 12 is increased. Thus, the area of the fin portion 12 in contact with the air is increased, increasing the heat dissipating capacity.

Following is a description of another example.

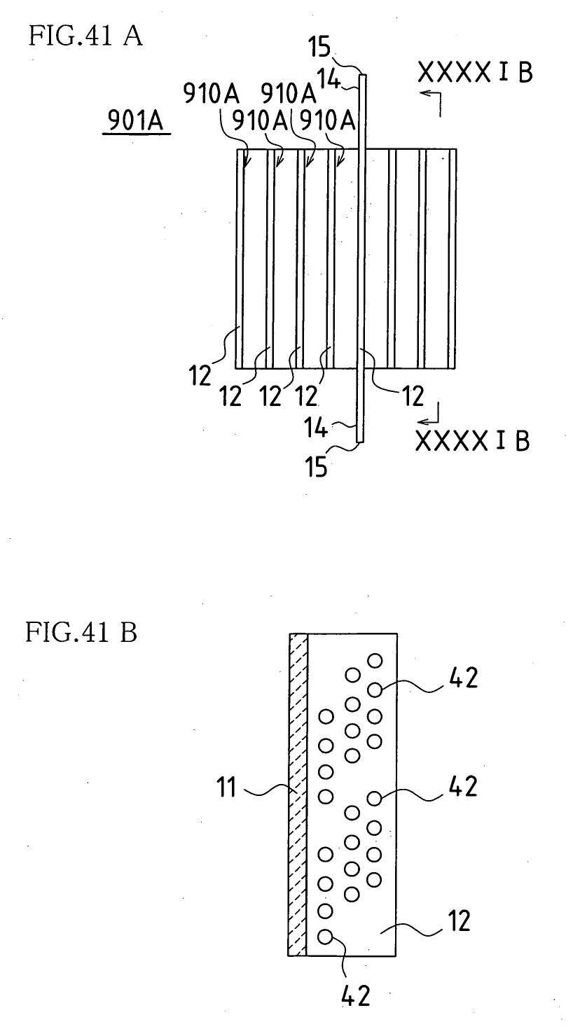

FIGS. 41A and 41B show a heat sink 901A according to a first modified example of Embodiment 9 of the present invention. FIG. 41A is a top view in which the heat sink 901A is viewed from above, and FIG. 41B is a side view in which the heat sink 901A is viewed from arrow XXXXIB.

In the heat dissipating members 910A, many through-holes (fin portion through-holes 42) are provided in the fin portion 12. The size of the fin portion through-holes 42 is preferably such that air can smoothly pass through. Thus, the surface area of the fin portion 12 can be increased, increasing the heat dissipating capacity. Also, by reducing the hole diameter of the fin portion through-holes 42, the heat dissipating capacity can be further increased. Also, the stagnation of air around the heat sink 1 can be prevented, and so the heat dissipating efficiency improves as a result.

Following is a description of still another example.

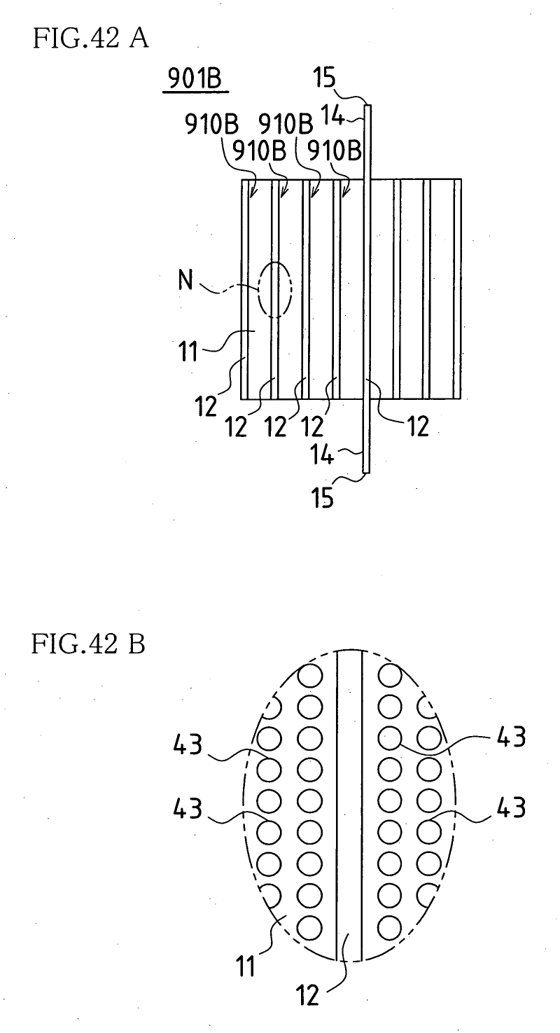

FIGS. 42A and 42B show a heat sink 901B according to a second modified example of Embodiment 9 of the present invention. FIG. 42A is a top view in which the heat sink 901B is viewed from above, and FIG. 42B is an enlarged view of a portion N.

In the heat dissipating members 910B, many through-holes (main body portion through-holes 43) are provided in the main body portion 11. The size of the main body portion through-holes 43 is preferably such that air can smoothly pass through. Thus, the surface area of the main body portion 11 increases, and so it is possible to increase the heat dissipating capacity.

### Embodiment 10

A heat sink 1001 according to the present embodiment has the similar structure to the heat sinks according to Embodiments 1 to 3. That is, the heat sink 1001 is configured by stacking heat dissipating members 1001a to 1001d (below, referred to together as the “heat dissipating members 1010” where necessary) at the main body portions 11. Also, the extended portion 14 is provided in at least one of the heat dissipating members 1010, and the engaging portion 15 is formed in the tip of the extended portion 14. The description of the constituent elements is similar to Embodiments 1 to 3, and therefore is omitted here. The positioning structure in Embodiment 4 or 5 may be adopted. Also, the joining structures of Embodiments 6 to 8 may be adopted. Also, a structure that improves the heat dissipating efficiency of Embodiment 9 may be adopted.

Here, the shape of fin portions 1012a to 1012d (below, referred to together as the “fin portions 1012” where necessary) of the heat sink 1001 will be described.

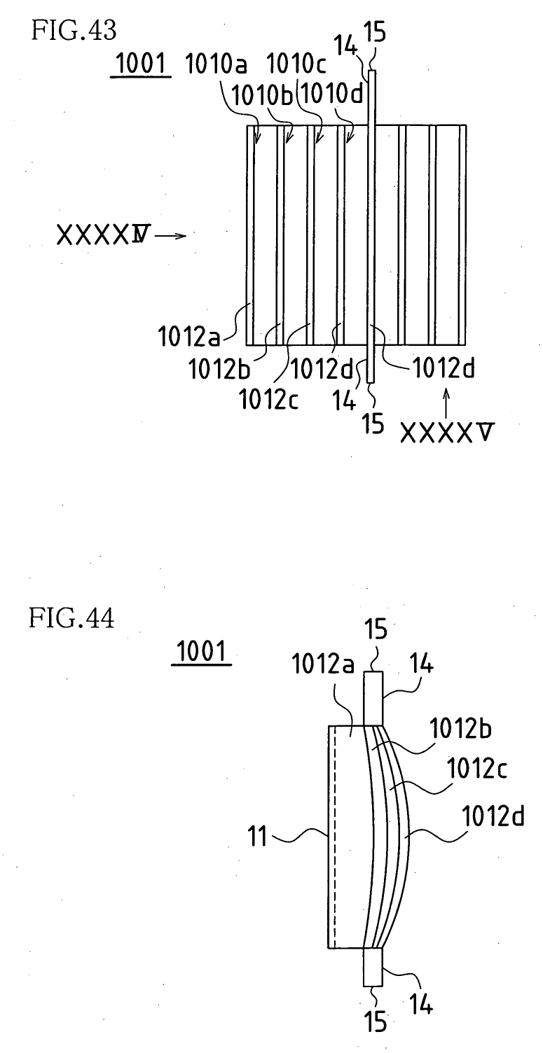

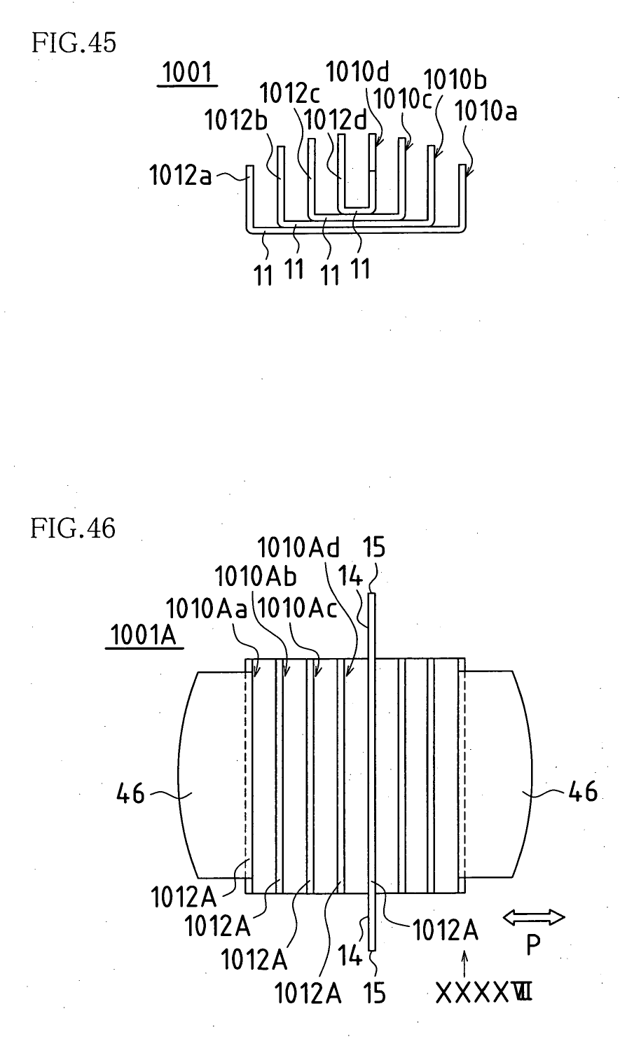

FIG. 43 is a top view in which the heat sink 1001 according to Embodiment 10 of the present invention is viewed from above. FIG. 44 is a side view in which the heat sink 1001 is viewed from arrow XXXXIV in FIG. 43. FIG. 45 is a side view in which the heat sink 1001 is viewed from arrow XXXXV in FIG. 43.

In the heat dissipating members 1010, the size of the fin portions 1012 is made to vary corresponding to the heat distribution in the electronic component 51. For example, in an IC, temperature becomes particularly high in the center portion, i.e., the portion where the IC chip, which is the source of heat generation, is disposed, and so the respective sizes of the fin portions 1012a to 1012d are made to correspond to this heat distribution.

Specifically, the fin portions 1012a to 1012d are formed in a mountain-like shape with a bulge in the center portion when viewed as a whole, such that the heat dissipating efficiency increases near the center of the heat sink 1001.

Thus, it is possible to avoid enlarging the fin portions 1012 more than necessary, so that the heat sink 1001 can be made smaller. That is, because the portion of the electronic component 51 in which the chip is equipped generates more heat than other portions, by enlarging the fin portion 1012 that corresponds to this portion and reducing the size of the other fin portions 1012 so that unnecessary fin portions 1012 are made smaller, the heat sink 1001 can be made smaller and lighter.

Following is a description of an example in which the fin portions 1012 of the heat sink 1001 are enlarged.

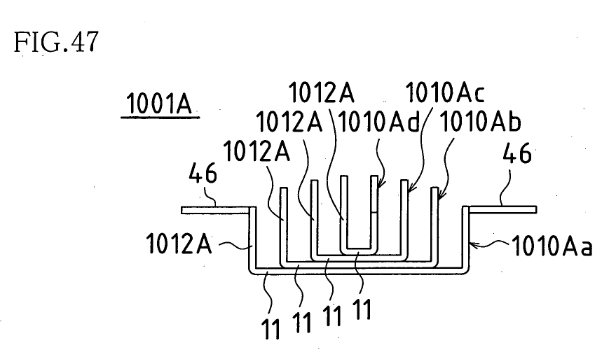

FIG. 46 is a top view in which a heat sink 1001A according to a modified example of Embodiment 10 of the present invention is viewed from above. FIG. 47 is a side view in which the heat sink 1001A is viewed from arrow XXXXVII in FIG. 46.

In a heat dissipating member 1010Ad that is furthest inside of heat dissipating members 1010Aa to 1010Ad (below, referred to together as the “heat dissipating members 1010A” where necessary) that configure the heat sink 1001A, heat dissipating extended portions 46 are formed extended and protruding from the fin portions 1012A. The heat dissipating extended portions 46 are formed such that they extend in the juxtaposed placement direction P of the fin portions 1012A. Specifically, they are formed by bending the fin portions 1012A.

Thus, because the surface area of the fin portions 1012A increases, the heat dissipating capacity can be increased. Also, because the fin portions 1012A are enlarged without increasing the dimensions of the main body portions 11, it is possible for the heat sink 1001A to have a small mounting area relative to the increase in heat dissipating capacity.

### Embodiment 11

Embodiment 11 will be described with reference to FIGS. 1 to 47. The electronic device 50 according to the present embodiment is configured by fitting any of the heat sinks according to Embodiments 1 to 10 to the back side of the electronic component 51, but here a case will be described in which the heat sink 1 in Embodiment 1 is used. The heat sink 1 is held by being engaged to the constituent members (the case 52, the mounting substrate 53, and the like) of the electronic device 50 by the engaging portion 15.

Specifically, the heat sink 1 is configured by stacking the heat dissipating members 10 at the main body portions 11. Also, the extended portion 14 is provided in at least one of the heat dissipating members 10, and the engaging portion 15 is formed in the tip of the extended portion 14. The engaging portion 15 is engaged and fixed to the catch portion 55, which has been formed in the side wall 52a of the case 52. Alternatively, the engaging portion 15 of the heat sink 1 is engaged and fixed to the catch portion 55, which has been formed in the mounting substrate 53.

Thus, the heat sink 1 is held by being engaged to the case 52 (or the mounting substrate 53 or the like), and so there is no risk of the heat sink 1 separating from the electronic component 51 due to long-term use of the electronic device 50. Also, because the gravitational force applied to the heat sink 1 is dispersed to the constituent members, it is possible to reduce the force applied to the contact face of the heat sink 1 and the electronic component 51, and so the heat sink 1 does not detach from the electronic component 51. Accordingly, because the heat-dissipating action of the electronic component 51 is insured for a long time, the reliability of the electronic device 50 improves.

Also, in the electronic device 50 with a configuration in which the engaging portion 15 of the heat sink 1 has been engaged to the case 52, the heat of the electronic component 51 is dissipated by being transmitted to the case 52 via the heat sink 1. Thus, the heat dissipating efficiency improves so that the operation of the electronic device 50 is stable.

Also, in the electronic device 50 with a configuration in which the engaging portion 15 of the heat sink 1 has been engaged to the mounting substrate 53, the heat of the electronic component 51 is transmitted to the heat sink 1 through the mounting substrate 53. Thus, the heat dissipating efficiency improves so that the operation of the electronic device 50 is stable.

The fin portions 12 may also have a height at which they are housed inside the case 52. Thus, the heat sink 1 is housed inside the case 52, so that the external view of the electronic device 50 becomes flat as a whole, and therefore it can be easily mounted. Also, because the entrance of foreign bodies from outside can be prevented, malfunction of the electronic device is eliminated.

The state in which the engaging portion 15 of the heat sink 1 and the catch portion 55 of the case 52 or the mounting substrate 53 are engaged is similar to Embodiments 1 to 3, and so that explanation is omitted here.

### Embodiment 12

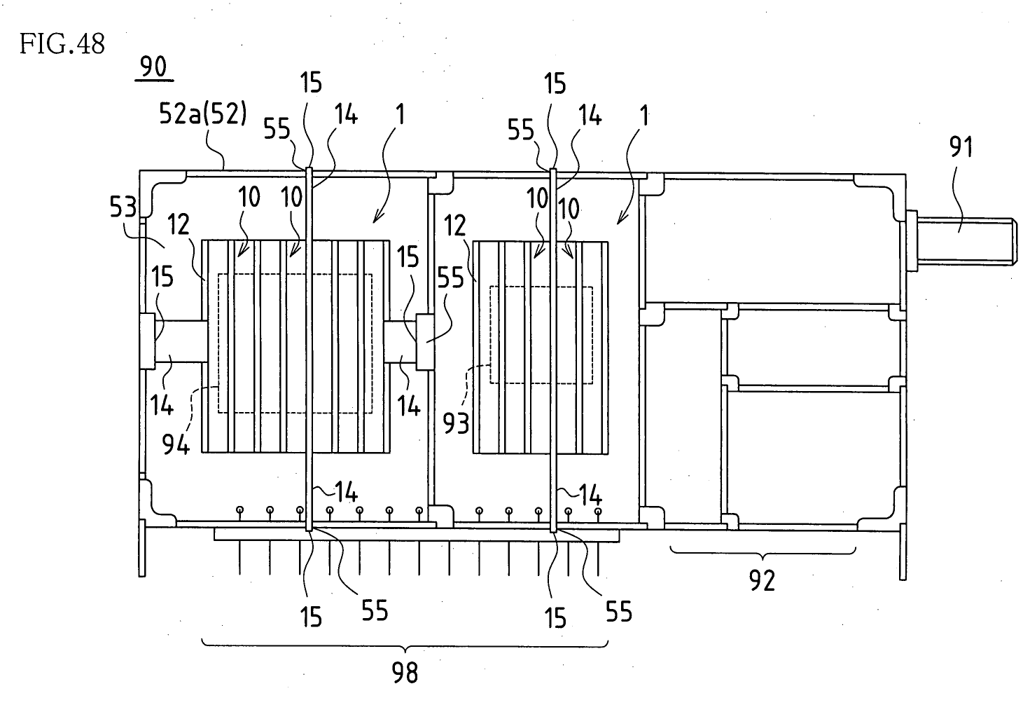

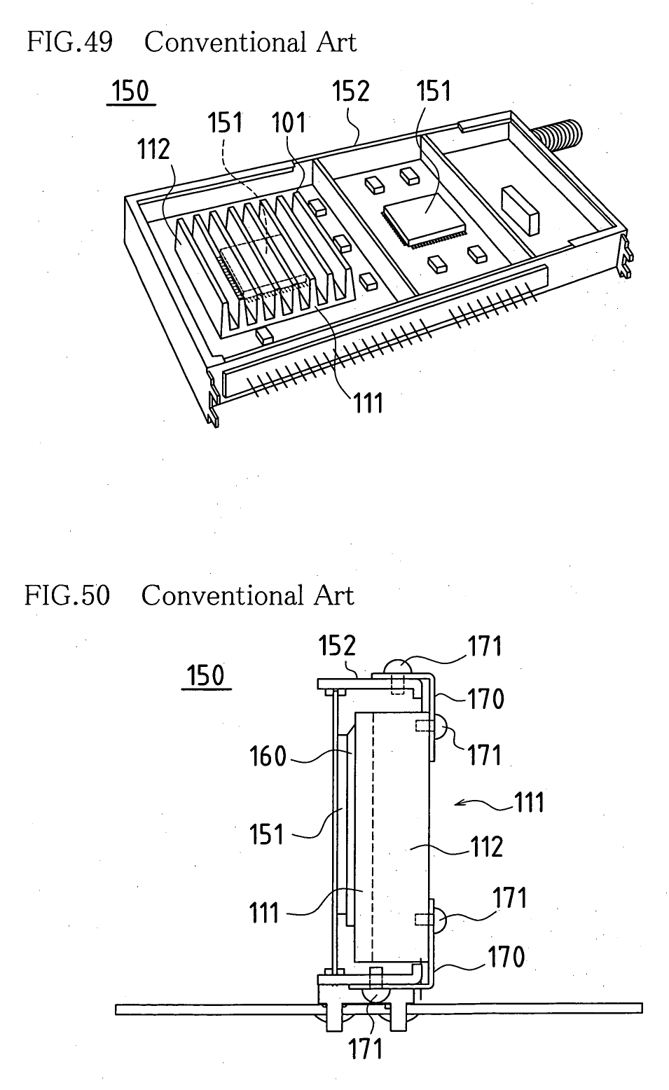

FIG. 48 is a top view in which a tuner apparatus 90 according to Embodiment 12 of the present invention is viewed from above. The tuner apparatus 90 according to the present embodiment is provided with an input portion 91 that inputs a high frequency signal, a high frequency processing portion 92 that processes a high frequency signal received by a receiving portion, and a video processing portion 98 that converts a signal formed by a receiving processing portion into a video signal. Also, any of the heat sinks of Embodiments 1 to 10 is fitted to LSI (Large Scale Integration) that configure the video processing portion 98, but here a case will be described in which the heat sink 1 in Embodiment 1 is used. In FIG. 48, the electronic component 51, which is not one of the main LSIs that configure the video processing portion 98, is omitted.

The input portion 91 is a portion for inputting a high frequency signal received with an antenna or the like, and is configured with a coaxial terminal. The high frequency processing portion 92 performs waveform processing and amplification of the high frequency signal input from the input portion 91.

The main portions of the video processing portion 98 are configured from a digital demodulation LSI 93 that digitally demodulates a signal output from the receiving processing portion, and a video processing LSI 94 that handles a video processing function that converts the digitally demodulated signal to a video signal. The signal processed by the high frequency processing portion 92 is digitally demodulated by the digital demodulation LSI 93, and processed into a video signal by the video processing LSI 94.

The heat sinks 1 of Embodiments 1 to 10 are fitted to the digital demodulation LSI 93 and the video processing LSI 94. Thus, the heat generated by the digital demodulation LSI 93 and the video processing LSI 94 is dissipated into the air, preventing a rise to extraordinarily high temperatures.

The heat sink 1 is configured by stacking the heat dissipating members 10 at the main body portions 11. Also, the extended portion 14 is provided in at least one of the heat dissipating members 10, and the engaging portion 15 is formed in the tip of the extended portion 14. The engaging portion 15 is engaged and fixed to the catch portion 55, which has been formed in the side wall 52a of the case 52. Alternatively, the engaging portion 15 of the heat sink 1 is engaged and fixed to the catch portion 55, which has been formed in the mounting substrate 53.

Thus, because the heat sink 1 is held by the case 52, the heat sink 1 does not separate from the digital demodulation LSI 93 or the video processing LSI 94.

For example, when the tuner apparatus 90 is disposed such that the back sides of the digital demodulation LSI 93 and the video processing LSI 94 are vertical, the gravitational force applied to the heat sink 1 is dispersed to the case 52 via the engaging portion 15. Thus, force that acts to strip away adhesion between the heat sink 1 and the digital demodulation LSI 93 (or the video processing LSI 94) weakens, and so the heat sink 1 does not strip away from the digital demodulation LSI 93 or the video processing LSI 94. Also, because the heat sink 1 is held by the case 52, the heat sink 1 does not separate from the digital demodulation LSI 93 or the video processing LSI 94 even when the adhesive force has weakened.

Accordingly, because the heat sink 1 effectively absorbs and dissipates heat from the digital demodulation LSI 93 or the video processing LSI 94 for a long time, the tuner apparatus 90 operates stably for a long time. That is, the reliability of the tuner apparatus 90 improves.

Also, the fitted heat sink 1 is configured so that the heat dissipating members 10 can be easily modified. Thus, even if the LSIs (the digital demodulation LSI 93 or the video processing LSI 94) are changed due to design modifications or the like, a suitable heat sink 1 can be fitted. That is, in the tuner apparatus 90, the heat dissipating members 10 can be appropriately modified in conformance with design modifications.

The tuner apparatus 90 is provided with a high frequency processing function, a digital demodulation function, and a video processing function, and so it can convert an input high frequency signal to a video signal and output that signal. Specifically, in a video device (for example, such as a television) that receives a high frequency signal and produces video, by using the tuner apparatus 90, an electrical circuit that performs digital demodulation and video processing does not need to be provided in a main substrate or the like of the main apparatus (video device).

The present invention may be embodied in various other forms without departing from the gist or essential characteristics thereof. The embodiments disclosed in this application are to be considered in all respects as illustrative and not limiting. The scope of the invention is indicated by the appended claims rather than by the foregoing description, and all modifications or changes that come within the meaning and range of equivalency of the claims are intended to be embraced therein.

1. A heat sink fitted to an electronic component, comprising:
a plurality of heat dissipating members each having
a flat main body portion and
a fin portion formed by extending the main body portion,
wherein at least one of the heat dissipating members further has
an extended portion formed by extending the fin portion or the main body portion, and
an engaging portion formed in a tip of the extended portion.

2. The heat sink according to claim 1, wherein the fin portions of the respective heat dissipating members are placed juxtaposed, and
the extended portion is formed in a direction that intersects the direction in which the fin portions are placed juxtaposed.

3. The heat sink according to claim 1, wherein the fin portions of the respective heat dissipating members are placed juxtaposed, and
the extended portion is formed in the direction in which the fin portions are placed juxtaposed.

4. The heat sink according to claim 1, wherein the fin portions of the respective heat dissipating members are placed juxtaposed, and
the extended portion is formed in a direction that intersects the direction in which the fin portions are placed juxtaposed and in the direction in which the fin portions are placed juxtaposed.

5. The heat sink according to claim 1, wherein the extended portion is formed by extending from both ends of a heat dissipating member.

6. The heat sink according to claim 1, wherein the engaging portion is formed in a convex shape relative to the tip end face of the extended portion.

7. The heat sink according to claim 1, wherein the engaging portion is formed in a concave shape relative to the tip end face of the extended portion.

8. The heat sink according to claim 1, wherein the engaging portion is formed in an L shape.

9. The heat sink according to claim 1, wherein the engaging portion is formed in a T shape.

10. The heat sink according to claim 5, wherein the engaging portion is a flat contact face that makes contact.

11. The heat sink according to claim 10, wherein the engaging portion is configured by forming a concave portion in the contact face.

12. The heat sink according to claim 10, wherein the engaging portion is configured by forming a convex portion in the contact face.

13. The heat sink according to claim 1, wherein the engaging portion engages to a case of an electronic device equipped with the electronic component.

14. The heat sink according to claim 1, wherein the engaging portion engages to a mounting substrate on which the electronic component is mounted.

15. The heat sink according to claim 1, wherein fitting portions that fit with each other are formed on both faces of the main body portion.

16. The heat sink according to claim 1, wherein the fin portion has a positioning portion that positions the main body portion by making contact with an adjacent fin portion.

17. The heat sink according to claim 1, wherein a joining member is provided that joins a plurality of the heat dissipating members stacked at the main body portions.

18. The heat sink according to claim 17, wherein the joining member is inserted into a through-hole formed in the main body portion, and the tip is deformed.

19. The heat sink according to claim 17, wherein the joining member is provided with
a male joining component and
a fitting component that fits with the male joining component such that it can be attached and removed, and
the male joining component is inserted in the through-hole formed in the main body portions and fitted with the fitting component.

20. The heat sink according to claim 1, wherein the heat dissipating members are stacked such that the end faces of the main body portions are even,
the furthest outside heat dissipating member has a protruding portion that protrudes from the end face, and
the protruding portion is deformed such that it presses against the main body portions.

21. The heat sink according to claim 20, wherein a concave-shaped fitting concave portion into which the protruding portion fits is each formed in the end faces of other heat dissipating members loaded on the furthest outside heat dissipating member.

22. The heat sink according to claim 21, wherein the fitting concave portion is a notch.

23. The heat sink according to claim 21, wherein the fitting concave portion is configured by a projection or projections provided in the end face of the main body portion.

24. The heat sink according to claim 1, wherein the heat dissipating members are welded to each other.

25. The heat sink according to claim 1, wherein the heat dissipating members are soldered to each other.

26. The heat sink according to claim 1, wherein the heat dissipating members are adhered to each other with thermally conductive adhesive.

27. The heat sink according to claim 1, wherein the heat dissipating members are adhered to each other with two-sided tape.

28. The heat sink according to claim 1, wherein at least one of the heat dissipating members is formed from aluminum.

29. The heat sink according to claim 1, wherein at least one of the heat dissipating members is formed from copper.

30. The heat sink according to claim 1, wherein the heat dissipating member having the engaging portion is formed from tin plate.

31. The heat sink according to claim 1, wherein convexo-concaves are formed on the surface of the fin portion.

32. The heat sink according to claim 1, wherein through-holes are provided in the fin portion.

33. The heat sink according to claim 1, wherein through-holes are provided in the main body portion.

34. The heat sink according to claim 1, wherein the height of the fin portion is allowed to vary according to the heat distribution in the electronic component.

35. The heat sink according to claim 1, wherein the fin portion is provided with a heat dissipating extended portion.

36. The heat sink according to claim 1, wherein the cross-sectional shape of the heat dissipating members is bathtub-like in a direction that intersects the direction in which the fin portions are placed juxtaposed.

37. An electronic device comprising:
an electronic component that generates heat due to the application of electricity,
a heat sink according to claim 1 fitted to the electronic component, and
a constituent member in which a catch portion is formed, wherein
the engaging portion of the heat sink is engaged to the catch portion.

38. An electronic device comprising:
an electronic component that generates heat due to the application of electricity,
a heat sink according to claim 6 fitted to the electronic component, and
a constituent member in which a concave catch portion that engages with the engaging portion of the heat sink is formed, wherein
the engaging portion of the heat sink is engaged to the catch portion.

39. An electronic device comprising:
an electronic component that generates heat due to the application of electricity,
a heat sink according to claim 7 fitted to the electronic component, and
a constituent member in which a convex catch portion that engages with the engaging portion of the heat sink is formed, wherein
the engaging portion of the heat sink is engaged to the catch portion.

40. An electronic device comprising:
an electronic component that generates heat due to the application of electricity,
a heat sink according to claim 8 fitted to the electronic component, and
a constituent member in which a catch portion is formed having
a catch main portion that engages with the engaging portion of the heat sink and
a fitting portion into which the tip of the engaging portion, having been deformed, is fit, wherein
the engaging portion of the heat sink is engaged to the catch portion.

41. An electronic device comprising:
an electronic component that generates heat due to the application of electricity,
a heat sink according to claim 9 fitted to the electronic component, and
a constituent member in which a concave catch portion is formed that engages with the engaging portion of the heat sink, wherein
the tip of the engaging portion is twisted, and
the engaging portion of the heat sink is engaged to the catch portion.

42. An electronic device comprising:
an electronic component that generates heat due to the application of electricity,
a heat sink according to claim 10 fitted to the electronic component, and
a constituent member in which a catch portion is formed that is made a contact portion in which the contact face is pushed against, wherein
the contact face is engaged to the catch portion.

43. The electronic device according to claim 37, wherein the constituent member is a case.

44. The electronic device according to claim 37, wherein the constituent member is a mounting substrate on which the electronic component is mounted.
